(19) United States
(12) Patent Application Publication
(10) Pub. No.: US 2023/0309310 A1
(43) Pub. Date: Sep. 28, 2023

(54) SEMICONDUCTOR DEVICE AND SEMICONDUCTOR MEMORY DEVICE

(71) Applicant: Kioxia Corporation, Tokyo (JP)

(72) Inventors: Yuta SAITO, Yokkaichi (JP); Shinji MORI, Nagoya (JP); Hiroyuki YAMASHITA, Yokkaichi (JP); Satoshi NAGASHIMA, Yokkaichi (JP); Kazuhiro MATSUO, Kuwana (JP); Kota TAKAHASHI, Yokkaichi (JP); Shota KASHIYAMA, Mie (JP); Keiichi SAWA, Yokkaichi (JP); Junichi KANEYAMA, Yokkaichi (JP)

(73) Assignee: Kioxia Corporation, Tokyo (JP)

(21) Appl. No.: 17/930,889

(22) Filed: Sep. 9, 2022

(30) Foreign Application Priority Data
Mar. 23, 2022 (JP) 2022-047565

(51) Int. Cl. H01L 27/1158; G11C 5/06; H01L 27/1157

(52) U.S. Cl. CPC H01L 27/1157; G11C 5/063; H01L 27/1158

(57) ABSTRACT

A semiconductor device of embodiments includes: a semiconductor layer containing silicon (Si); a first insulating layer provided in a first direction of the semiconductor layer; a second insulating layer surrounded by the semiconductor layer in a first cross section perpendicular to the first direction and containing silicon (Si) and oxygen (O); a third insulating layer surrounded by the second insulating layer in the first cross section and containing a metal element and oxygen (O); and a conductive layer surrounded by the first insulating layer in a second cross section perpendicular to the first direction, provided in the first direction of the third insulating layer, and spaced from the semiconductor layer.

### CROSS-REFERENCE TO RELATED APPLICATION

This application is based upon and claims the benefit of priority from Japanese Patent Application No. 2022-047565, filed on Mar. 23, 2022, the entire contents of which are incorporated herein by reference.

### FIELD

Embodiments described herein relate generally to a semiconductor device and a semiconductor memory device.

### BACKGROUND

A three-dimensional NAND flash memory in which memory cells are three-dimensionally arranged realizes a high degree of integration and a low cost. In the three-dimensional NAND flash memory, for example, a memory hole penetrating a stacked body is formed in the stacked body in which a plurality of insulating layers and a plurality of gate electrode layers are alternately stacked. By forming a charge storage layer and a semiconductor layer in the memory hole, a memory string in which a plurality of memory cells are connected in series to each other is formed. Data is stored in the memory cells by controlling the amount of charge stored in the charge storage layer.

### BRIEF DESCRIPTION OF THE DRAWINGS

FIG. 1 is a schematic cross-sectional view of a semiconductor device according to a first embodiment;

FIG. 2 is a schematic cross-sectional view of the semiconductor device according to the first embodiment;

FIG. 3 is a schematic cross-sectional view of the semiconductor device according to the first embodiment;

FIG. 4 is an explanatory diagram of a method for manufacturing the semiconductor device according to the first embodiment;

FIG. 5 is an explanatory diagram of the method for manufacturing the semiconductor device according to the first embodiment;

FIG. 6 is an explanatory diagram of the method for manufacturing the semiconductor device according to the first embodiment;

FIG. 7 is an explanatory diagram of the method for manufacturing the semiconductor device according to the first embodiment;

FIG. 8 is an explanatory diagram of the method for manufacturing the semiconductor device according to the first embodiment;

FIG. 9 is an explanatory diagram of the method for manufacturing the semiconductor device according to the first embodiment;

FIG. 10 is an explanatory diagram of the method for manufacturing the semiconductor device according to the first embodiment;

FIG. 11 is an explanatory diagram of the method for manufacturing the semiconductor device according to the first embodiment;

FIG. 12 is a schematic cross-sectional view of a semiconductor device of a comparative example;

FIG. 13 is an explanatory diagram of the function and effect of the method for manufacturing the semiconductor device according to the first embodiment;

FIG. 14 is a schematic cross-sectional view of a semiconductor device of a modification example of the first embodiment;

FIG. 15 is an explanatory diagram of the function and effect of a method for manufacturing the semiconductor device of the modification example of the first embodiment;

FIG. 16 is a circuit diagram of a main part of a semiconductor memory device according to a second embodiment;

FIG. 17 is a schematic cross-sectional view of the main part of the semiconductor memory device according to the second embodiment;

FIGS. 18A and 18B are schematic cross-sectional views of a memory cell array of the semiconductor memory device according to the second embodiment;

FIGS. 19A, 19B, 19C, and 19D are schematic cross-sectional views of the semiconductor memory device according to the second embodiment;

FIG. 20 is an explanatory diagram of a method for manufacturing the semiconductor memory device according to the second embodiment;

FIG. 21 is an explanatory diagram of the method for manufacturing the semiconductor memory device according to the second embodiment;

FIG. 22 is an explanatory diagram of the method for manufacturing the semiconductor memory device according to the second embodiment;

FIG. 23 is an explanatory diagram of the method for manufacturing the semiconductor memory device according to the second embodiment;

FIG. 24 is an explanatory diagram of the method for manufacturing the semiconductor memory device according to the second embodiment;

FIG. 25 is an explanatory diagram of the method for manufacturing the semiconductor memory device according to the second embodiment;

FIG. 26 is an explanatory diagram of the method for manufacturing the semiconductor memory device according to the second embodiment;

FIG. 27 is an explanatory diagram of the method for manufacturing the semiconductor memory device according to the second embodiment;

FIG. 28 is an explanatory diagram of the method for manufacturing the semiconductor memory device according to the second embodiment;

FIG. 29 is an explanatory diagram of the method for manufacturing the semiconductor memory device according to the second embodiment;

FIG. 30 is an explanatory diagram of the method for manufacturing the semiconductor memory device according to the second embodiment;

FIG. 31 is an explanatory diagram of the method for manufacturing the semiconductor memory device according to the second embodiment;

FIG. 32 is an explanatory diagram of the method for manufacturing the semiconductor memory device according to the second embodiment;

FIG. 33 is an explanatory diagram of the method for manufacturing the semiconductor memory device according to the second embodiment;

FIG. 34 is an explanatory diagram of the method for manufacturing the semiconductor memory device according to the second embodiment;

FIG. 35 is an explanatory diagram of the method for manufacturing the semiconductor memory device according to the second embodiment;

FIG. 36 is an explanatory diagram of the method for manufacturing the semiconductor memory device according to the second embodiment;

FIG. 37 is an explanatory diagram of the method for manufacturing the semiconductor memory device according to the second embodiment;

FIG. 38 is an explanatory diagram of the method for manufacturing the semiconductor memory device according to the second embodiment;

FIG. 39 is an explanatory diagram of the method for manufacturing the semiconductor memory device according to the second embodiment;

FIG. 40 is an explanatory diagram of the method for manufacturing the semiconductor memory device according to the second embodiment;

FIGS. 41A and 41B are schematic cross-sectional views of a memory cell array of a semiconductor memory device of a modification example of the second embodiment;

FIG. 42 is a circuit diagram of a main part of a semiconductor memory device according to a third embodiment;

FIGS. 43A and 43B are schematic cross-sectional views of a memory cell array of the semiconductor memory device according to the third embodiment;

FIG. 44 is an explanatory diagram of the method for manufacturing the semiconductor memory device according to the third embodiment;

FIG. 45 is an explanatory diagram of the method for manufacturing the semiconductor memory device according to the third embodiment;

FIG. 46 is an explanatory diagram of the method for manufacturing the semiconductor memory device according to the third embodiment;

FIG. 47 is an explanatory diagram of the method for manufacturing the semiconductor memory device according to the third embodiment;

FIG. 48 is an explanatory diagram of the method for manufacturing the semiconductor memory device according to the third embodiment;

FIG. 49 is an explanatory diagram of the method for manufacturing the semiconductor memory device according to the third embodiment;

FIG. 50 is an explanatory diagram of the method for manufacturing the semiconductor memory device according to the third embodiment;

FIG. 51 is an explanatory diagram of the method for manufacturing the semiconductor memory device according to the third embodiment; and

FIG. 52 is an explanatory diagram of the method for manufacturing the semiconductor memory device according to the third embodiment.

### DETAILED DESCRIPTION

A semiconductor device of embodiments includes: a semiconductor layer containing silicon (Si); a first insulating layer provided in a first direction of the semiconductor layer; a second insulating layer surrounded by the semiconductor layer in a first cross section perpendicular to the first direction and containing silicon (Si) and oxygen (O); a third insulating layer surrounded by the second insulating layer in the first cross section and containing a metal element and oxygen (O); and a conductive layer surrounded by the first insulating layer in a second cross section perpendicular to the first direction, provided in the first direction of the third insulating layer, and spaced from the semiconductor layer.

Hereinafter, embodiments will be described with reference to the diagrams. In the following description, the same or similar members and the like may be denoted by the same reference numerals, and the description of the members and the like once described may be omitted as appropriate.

In addition, in this specification, terms such as “on”, “above”, “under”, and “below” may be used for convenience. The terms “on”, “above”, “under”, and “below” are, for example, terms indicating the relative positional relationships in the diagrams. The terms “on”, “above”, “under”, and “below” do not necessarily define the positional relationship with gravity.

The qualitative analysis and quantitative analysis of the chemical composition of the members forming the semiconductor device or the semiconductor memory device in this specification can be performed by using, for example, secondary ion mass spectrometry (SIMS) and energy dispersive X-ray spectroscopy (EDX). In addition, when measuring the thickness of each member forming the semiconductor device or the semiconductor memory device, a distance between members, and the like, it is possible to use, for example, a transmission electron microscope (TEM).

### First Embodiment

A semiconductor device according to a first embodiment includes: a semiconductor layer containing silicon (Si); a first insulating layer provided in a first direction of the semiconductor layer; a second insulating layer surrounded by the semiconductor layer in a first cross section perpendicular to the first direction and containing silicon (Si) and oxygen (O); a third insulating layer surrounded by the second insulating layer in the first cross section and containing a metal element and oxygen (O); and a conductive layer surrounded by the first insulating layer in a second cross section perpendicular to the first direction, provided in the first direction of the third insulating layer, and spaced from the semiconductor layer.

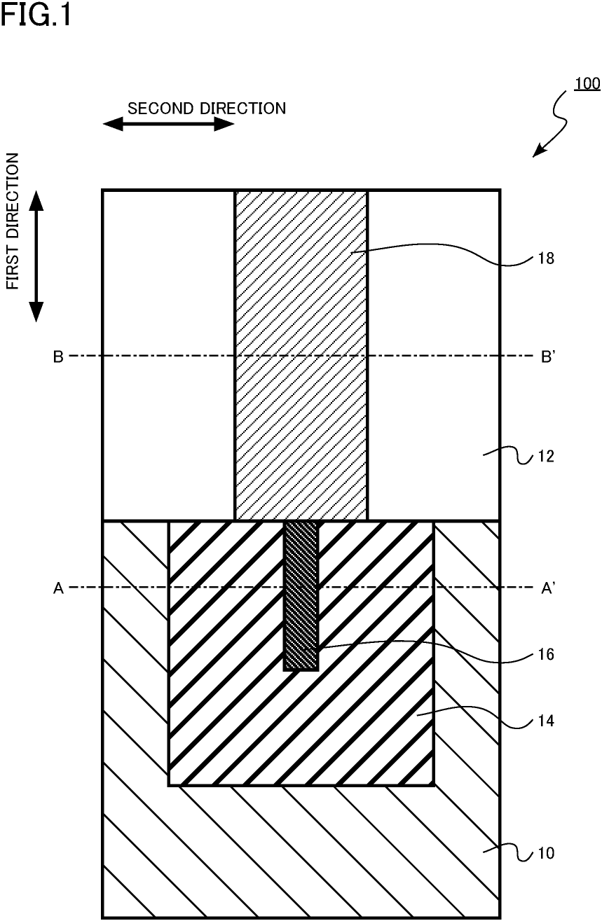

FIGS. 1, 2, and 3 are schematic cross-sectional views of the semiconductor device according to the first embodiment. The semiconductor device according to the first embodiment includes an insulating structure 100. The insulating structure 100 is a structure for electrically separating a conductive layer and a semiconductor layer from each other. The insulating structure 100 is a structure for maintaining insulation between the conductive layer and the semiconductor layer.

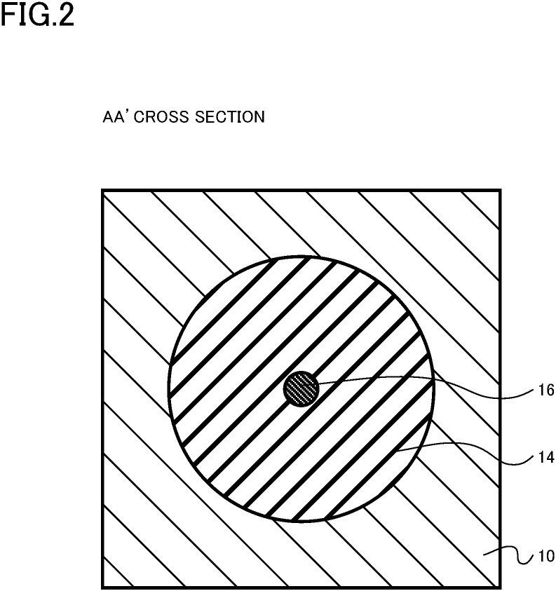

FIG. 2 is a cross-sectional view taken along the line AA′ of FIG. 1. The AA′ cross section is a cross section perpendicular to the first direction. The AA′ cross section is an example of the first cross section.

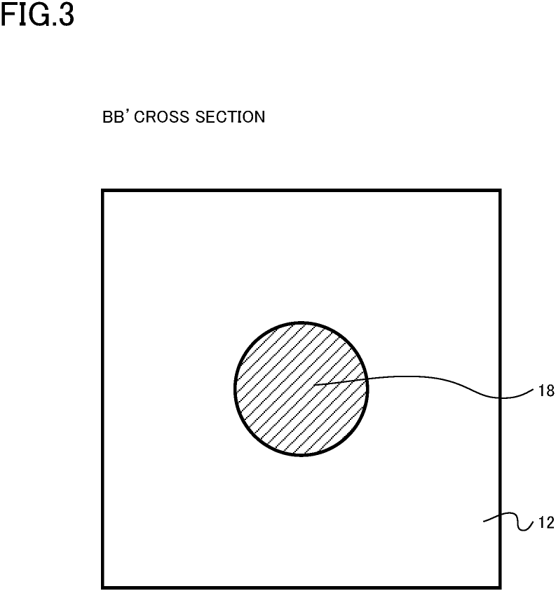

FIG. 3 is a cross-sectional view taken along the line BB′ of FIG. 1. The BB′ cross section is a cross section perpendicular to the first direction. The BB′ cross section is an example of the second cross section.

The insulating structure 100 includes a semiconductor layer 10, a first insulating layer 12, a second insulating layer 14, a third insulating layer 16, and a conductive layer 18.

The first direction is a direction perpendicular to the surface of the semiconductor layer 10. The second direction is a direction perpendicular to the first direction.

The semiconductor layer 10 contains silicon (Si). The semiconductor layer 10 contains, for example, silicon (Si) as a main component. The fact that the semiconductor layer 10 contains silicon (Si) as a main component means that, among the elements contained in the semiconductor layer 10, there is no element having a higher content ratio than silicon (Si). The semiconductor layer 10 is, for example, a single crystal silicon layer or a polycrystalline silicon layer.

The semiconductor layer 10 is not limited to the single crystal silicon layer or the polycrystalline silicon layer. The semiconductor layer 10 may be, for example, a silicon germanide layer or a silicon carbide layer.

The first insulating layer 12 is provided in the first direction of the semiconductor layer 10. The first insulating layer 12 is provided on, for example, the semiconductor layer 10. The first insulating layer 12 is in contact with, for example, the semiconductor layer 10.

The first insulating layer 12 contains, for example, oxide. The first insulating layer 12 contains, for example, silicon (Si) and oxygen (O). The first insulating layer 12 contains, for example, silicon oxide. The first insulating layer 12 is, for example, a silicon oxide.

The first insulating layer 12 contains, for example, nitride. The first insulating layer 12 contains, for example, silicon (Si) and nitrogen (N). The first insulating layer 12 contains, for example, silicon nitride. The first insulating layer 12 is, for example, a silicon nitride.

The first insulating layer 12 contains, for example, oxynitride. The first insulating layer 12 contains, for example, silicon (Si), oxygen (O), and nitrogen (N). The first insulating layer 12 contains, for example, silicon oxynitride. The first insulating layer 12 is, for example, a silicon oxynitride.

The second insulating layer 14 is surrounded by the semiconductor layer 10 in the first cross section perpendicular to the first direction. For example, as shown in FIG. 2, the second insulating layer 14 is surrounded by the semiconductor layer 10 in the AA′ cross section. The second insulating layer 14 is in contact with, for example, the semiconductor layer 10.

The second insulating layer 14 contains silicon (Si) and oxygen (O). The second insulating layer 14 contains, for example, silicon (Si) and oxygen (O) as main components. The fact that the second insulating layer 14 contains silicon (Si) and oxygen (O) as main components means that, among the elements contained in the second insulating layer 14, there is no element having a higher content ratio than silicon (Si) and oxygen (O).

The second insulating layer 14 contains, for example, silicon oxide. The second insulating layer 14 is, for example, a silicon oxide.

The third insulating layer 16 is surrounded by the second insulating layer 14 in the first cross section perpendicular to the first direction. For example, as shown in FIG. 2, the third insulating layer 16 is surrounded by the second insulating layer 14 in the AA′ cross section. The third insulating layer 16 is spaced from the semiconductor layer 10, for example.

The third insulating layer 16 is provided in the first direction of the conductive layer 18. The third insulating layer 16 is provided under the conductive layer 18. The third insulating layer 16 is provided directly under the conductive layer 18.

The third insulating layer 16 contains a metal element and oxygen (O). The metal element contained in the third insulating layer 16 is, for example, at least one metal element selected from the group consisting of aluminum (Al), hafnium (Hf), zirconium (Zr), lanthanum (La), yttrium (Y), titanium (Ti), nickel (Ni), zinc (Zn), indium (In), tin (Sn), gallium (Ga), and tungsten (W).

The third insulating layer 16 contains, for example, the above-described metal element and oxygen (O) as main components. The fact that the third insulating layer 16 contains the above-described metal element and oxygen (O) as main components means that, among the elements contained in the third insulating layer 16, there is no element having a higher content ratio than the above-described metal element and oxygen (O).

The third insulating layer 16 contains, for example, metal oxide. The third insulating layer 16 contains, for example, oxide of the above-described metal element.

The third insulating layer 16 contains, for example, aluminum oxide, hafnium oxide, zirconium oxide, lanthanum oxide, yttrium oxide, titanium oxide, nickel oxide, zinc oxide, indium oxide, tin oxide, gallium oxide, or tungsten oxide. The third insulating layer 16 is, for example, an aluminum oxide, a hafnium oxide, a zirconium oxide, a lanthanum oxide, an yttrium oxide, a titanium oxide, a nickel oxide, a zinc oxide, an indium oxide, a tin oxide, a gallium oxide, or a tungsten oxide.

The chemical composition of the third insulating layer 16 is different from, for example, the chemical composition of the second insulating layer 14. The dielectric constant of the third insulating layer 16 is, for example, higher than the dielectric constant of the second insulating layer 14.

The width of the third insulating layer 16 in the second direction is, for example, equal to or more than 2 nm and equal to or less than 10 nm. The width of the second insulating layer 14 in the second direction is, for example, equal to or more than 3 times and equal to or less than 20 times the width of the third insulating layer 16 in the second direction.

The conductive layer 18 is surrounded by the first insulating layer 12 in the second cross section perpendicular to the first direction. For example, as shown in FIG. 3, the conductive layer 18 is surrounded by the first insulating layer 12 in the BB′ cross section. The conductive layer 18 is in contact with, for example, the first insulating layer 12.

The conductive layer 18 is provided in the first direction of the third insulating layer 16. The conductive layer 18 is in contact with, for example, the third insulating layer 16. The conductive layer 18 is in contact with, for example, the second insulating layer 14.

The width of the conductive layer 18 in the second direction is smaller than, for example, the width of the second insulating layer 14 in the second direction.

The conductive layer 18 is, for example, a metal, a metal compound, or a semiconductor. The conductive layer 18 contains, for example, tungsten (W), molybdenum (Mo), ruthenium (Ru), or titanium (Ti). The conductive layer 18 contains, for example, polycrystalline silicon.

Next, an example of a method for manufacturing the semiconductor device according to the first embodiment will be described.

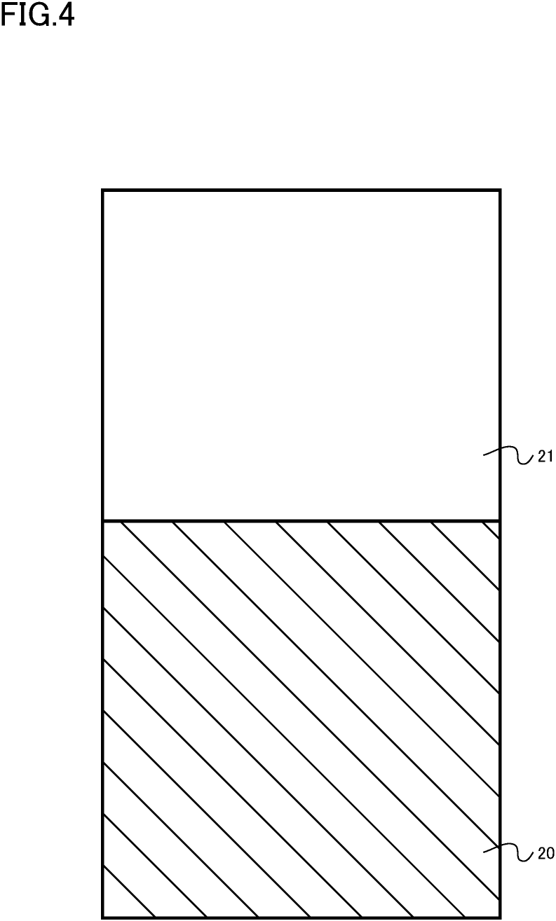

FIGS. 4 to 11 are explanatory diagrams of the method for manufacturing the semiconductor device according to the first embodiment. FIGS. 4 to 11 are cross-sectional views corresponding to FIG. 1. FIGS. 4 to 11 show an example of the method for manufacturing the insulating structure 100 according to the first embodiment.

Hereinafter, a case where the semiconductor layer 10 is single crystal silicon, the first insulating layer 12 is a silicon oxide, the second insulating layer 14 is a silicon oxide, the third insulating layer 16 is an aluminum oxide, and the conductive layer 18 is tungsten (W) will be described as an example.

First, a first silicon oxide film 21 is formed on a single crystal silicon layer 20 (FIG. 4). The first silicon oxide film 21 is formed by using, for example, a chemical vapor deposition method (CVD method).

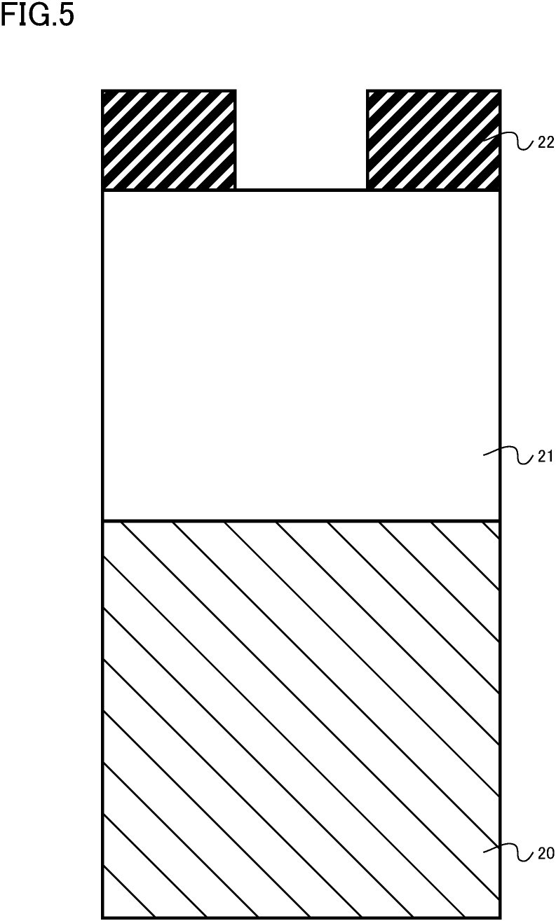

Then, a patterned resist film 22 is formed on the first silicon oxide film 21 (FIG. 5). The resist film 22 is formed by using a photolithography method.

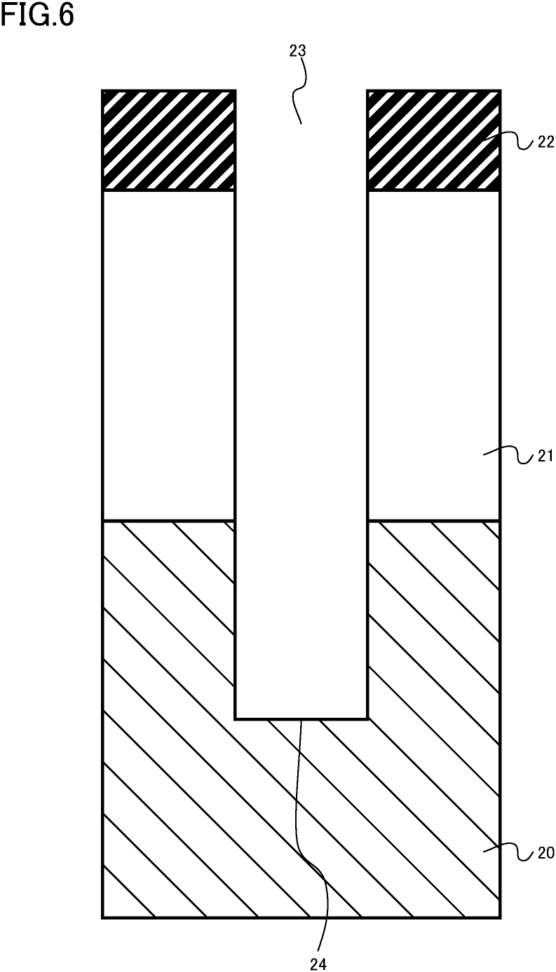

Then, an opening 23 is formed by using the resist film 22 as a mask (FIG. 6). The opening 23 penetrates the first silicon oxide film 21 to form a recess 24 in the single crystal silicon layer 20. The opening 23 is formed by using, for example, a reactive ion etching method (RIE method).

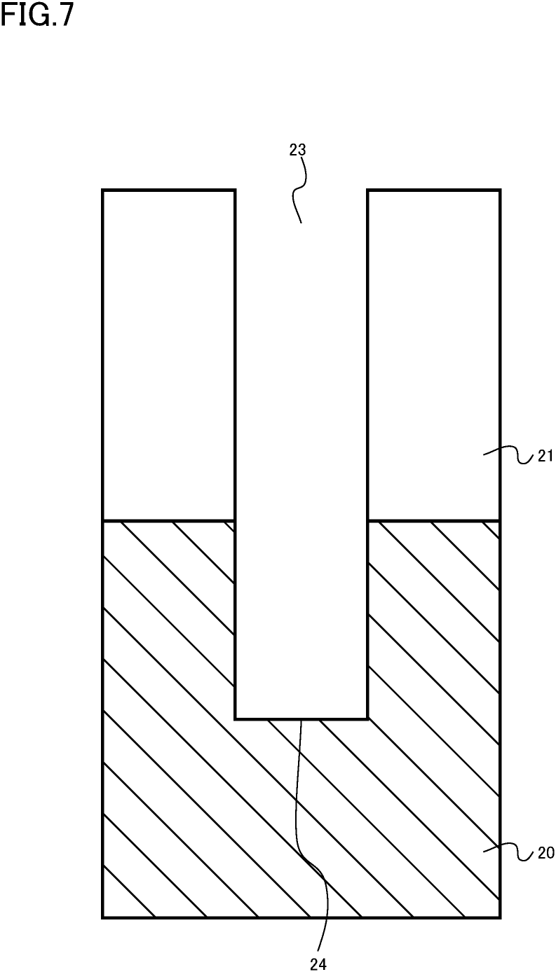

Then, the resist film 22 is removed (FIG. 7). The resist film 22 is removed by, for example, ashing.

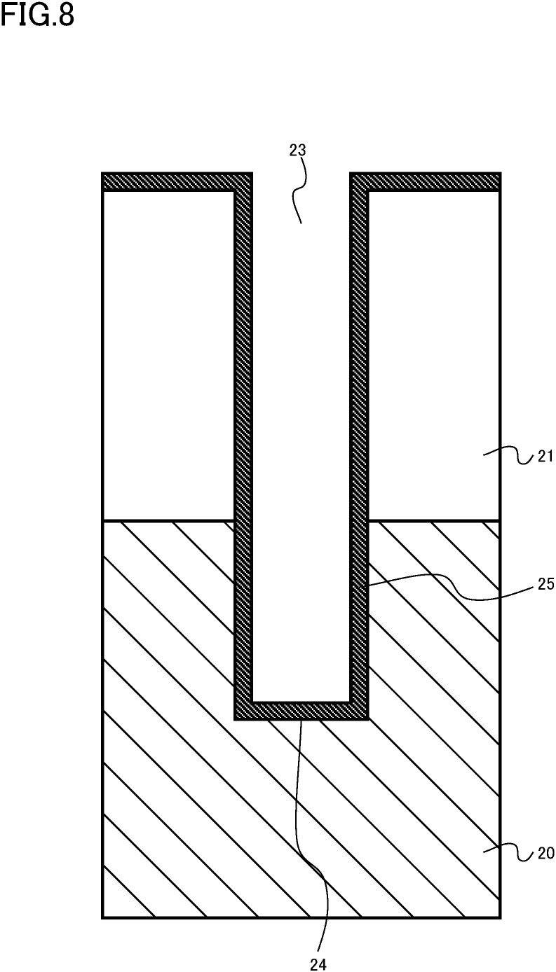

Then, an aluminum oxide film 25 is formed in the opening 23 (FIG. 8). The aluminum oxide film 25 is formed by using, for example, an atomic layer deposition method (ALD method). The thickness of the aluminum oxide film 25 is, for example, equal to or more than 1 nm and equal to or less than 5 nm.

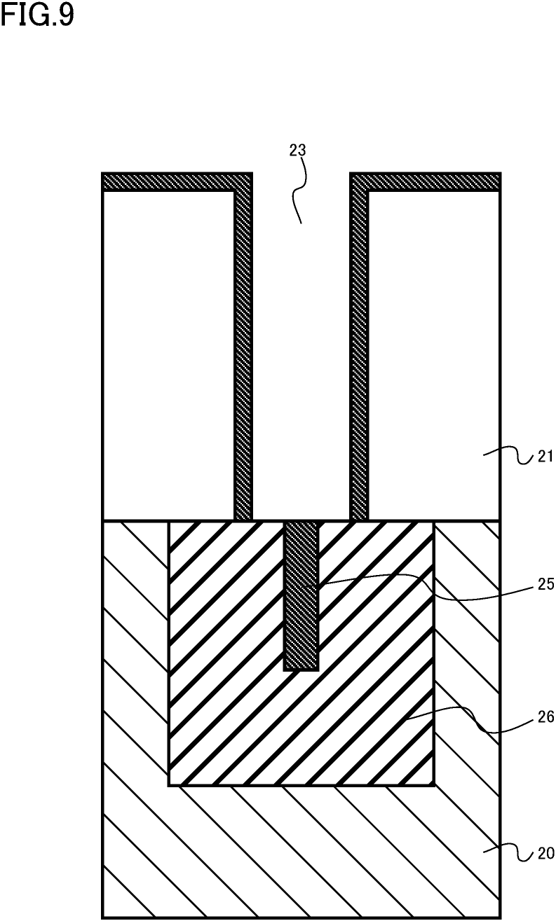

Then, a second silicon oxide film 26 is formed between the single crystal silicon layer 20 and the aluminum oxide film 25 by using radical oxidation (FIG. 9). By oxidizing the single crystal silicon layer 20 by radical oxidation, the second silicon oxide film 26 is formed.

Radical oxidation is performed in an atmosphere containing oxygen radicals or hydroxyl radicals. For example, radical oxidation is performed in an atmosphere in which oxygen gas, hydrogen gas, and argon gas are turned into plasma. For example, radical oxidation is performed in an atmosphere in which water vapor is turned into plasma.

The method for generating oxygen radicals or hydroxyl radicals used for radical oxidation is not particularly limited. Oxygen radicals or hydroxyl radicals are generated by using, for example, an inductively coupled plasma method, a microwave plasma method, an electron cyclotron resonance method, a helicon wave method, or a thermal filament method.

The temperature of radical oxidation is, for example, equal to or more than 300° C. and equal to or less than 900° C. The pressure of radical oxidation is, for example, equal to or more than 50 Pa and equal to or less than 3000 Pa.

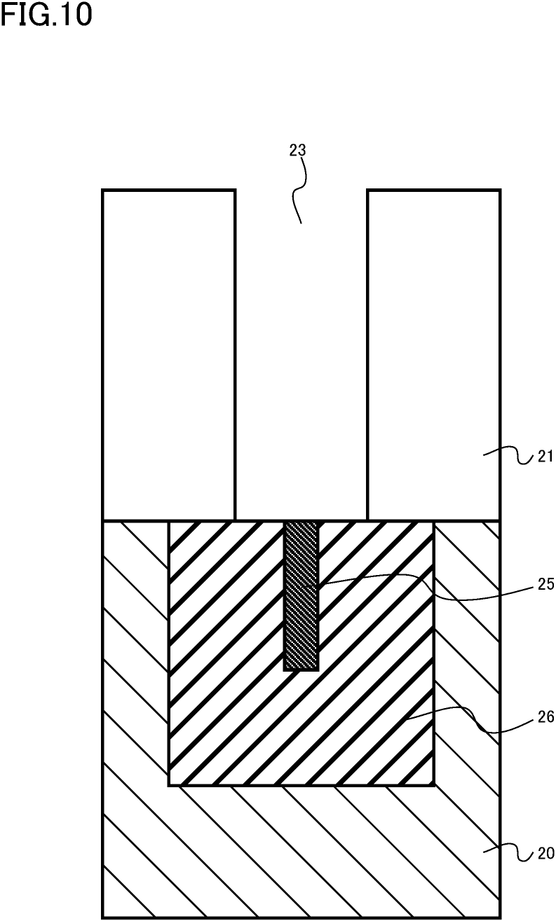

Then, the aluminum oxide film 25 inside the opening 23 and on the surface of the first silicon oxide film 21 is removed (FIG. 10). The aluminum oxide film 25 is removed by using, for example, a wet etching method.

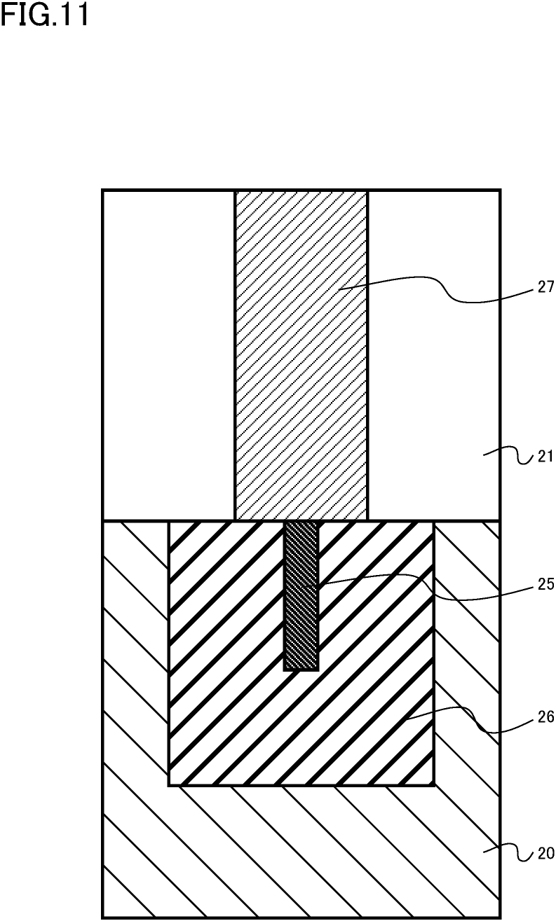

Then, the inside of the opening 23 is buried with a tungsten film 27 (FIG. 11). The tungsten film 27 is formed by using, for example, a CVD method.

By the manufacturing method described above, the insulating structure 100 shown in FIGS. 1, 2, and 3 is formed.

Next, the function and effect of the semiconductor device according to the first embodiment will be described.

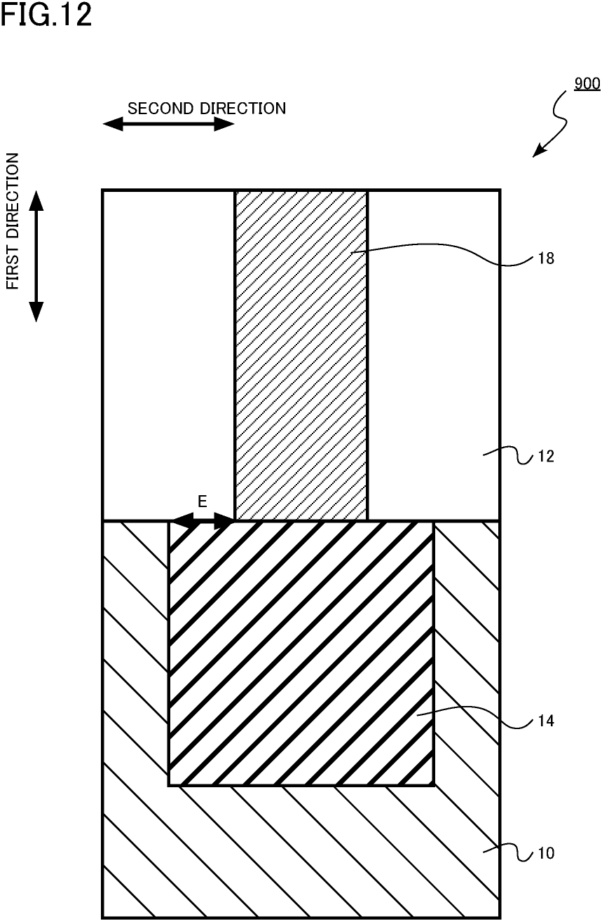

FIG. 12 is a schematic cross-sectional view of a semiconductor device of a comparative example. The semiconductor device of the comparative example includes an insulating structure 900. The insulating structure 900 is a structure for electrically separating a conductive layer and a semiconductor layer from each other.

The insulating structure 900 of the comparative example includes a semiconductor layer 10, a first insulating layer 12, a second insulating layer 14, and a conductive layer 18. The insulating structure 900 of the comparative example is different from the insulating structure 100 according to the first embodiment in that the insulating structure 900 of the comparative example does not include the third insulating layer 16.

The insulating structure 900 is a structure for maintaining electrical insulation between the conductive layer 18 and the semiconductor layer 10. By providing the second insulating layer 14 between the conductive layer 18 and the semiconductor layer 10, the electrical insulation between the conductive layer 18 and the semiconductor layer 10 is maintained.

However, for example, as the distance between the conductive layer 18 and the semiconductor layer 10 decreases, the electric field strength between the conductive layer 18 and the semiconductor layer 10 increases. For example, as shown in FIG. 12, an electric field strength E at a portion where the distance between the conductive layer 18 and the semiconductor layer 10 is minimized increases. As the electric field strength E increases, a leakage current is likely to flow between the conductive layer 18 and the semiconductor layer 10, so that the electrical insulation between the conductive layer 18 and the semiconductor layer 10 is lowered.

In the insulating structure 100 according to the first embodiment, the third insulating layer 16 having a higher dielectric constant than the second insulating layer 14 is provided under the conductive layer 18. By providing the third insulating layer 16 having a high dielectric constant, the line of electric force between the conductive layer 18 and the semiconductor layer 10 is distributed, so that the electric field strength between the conductive layer 18 and the semiconductor layer 10 is reduced. For example, the electric field strength E at a portion where the distance between the conductive layer 18 and the semiconductor layer 10 is minimized is reduced. Since the electric field strength E is reduced, the leakage current between the conductive layer 18 and the semiconductor layer 10 is suppressed, so that the electrical insulation between the conductive layer 18 and the semiconductor layer 10 is improved. Therefore, the characteristics of the semiconductor device including the insulating structure 100 are improved.

As described above, the second insulating layer 14 forming the insulating structure 100 is formed by radical oxidation after forming a metal oxide film, such as an aluminum oxide film, on the semiconductor layer. According to the studies by the inventors, it has been clarified that, by combining the metal oxide film and radical oxidation, the semiconductor layer can be oxidized thicker at a lower temperature than in the case of, for example, thermal oxidation.

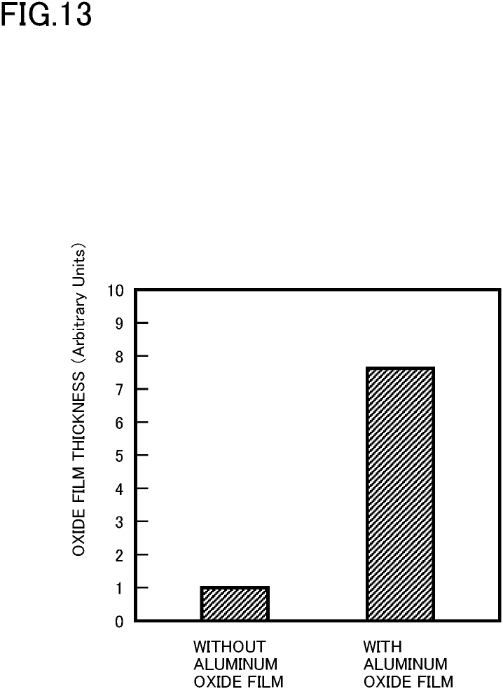

FIG. 13 is an explanatory diagram of the function and effect of the method for manufacturing the semiconductor device according to the first embodiment. FIG. 13 is a diagram showing the thickness of an oxide film formed by oxidizing the semiconductor layer by radical oxidation.

FIG. 13 is a diagram for comparing the oxide film thickness when the metal oxide film is formed on the semiconductor layer and the oxide film thickness when the metal oxide film is not formed. FIG. 13 shows a case where the semiconductor layer is a single crystal silicon layer and the metal oxide film is an aluminum oxide film. FIG. 13 shows a case where the thickness of the aluminum oxide film is 3 nm and the temperature of radical oxidation is 700° C.

As is apparent from FIG. 13, it can be seen that the oxide film thickness when the aluminum oxide film is formed on the semiconductor layer to perform radical oxidation is equal to or more than 7 times the oxide film thickness when the aluminum oxide film is not formed. In other words, it can be seen that large accelerated oxidation occurs by forming the aluminum oxide film on the semiconductor layer to perform radical oxidation.

The mechanism by which large accelerated oxidation occurs as shown in FIG. 13 is not always clear. However, it is considered that the presence of a film in which a metal element and oxygen (O) coexist on the semiconductor layer containing silicon lowers the activation energy for forming an oxide film and accordingly, accelerated oxidation occurs. In addition, it is considered that an oxygen-deficient portion in the metal oxide is filled with oxygen radicals or hydroxyl radicals and then oxygen in the metal oxide is expelled by the oxygen radicals or hydroxyl radicals that have invaded the metal oxide and accordingly, accelerated oxidation occurs.

The insulating structure 100 according to the first embodiment including the third insulating layer 16 can be easily formed at a low temperature. Therefore, for example, even if an element having low heat resistance is formed in the semiconductor device before the insulating structure 100 is formed, degradation of the characteristics of the element due to heat treatment can be suppressed.

### Modification Example

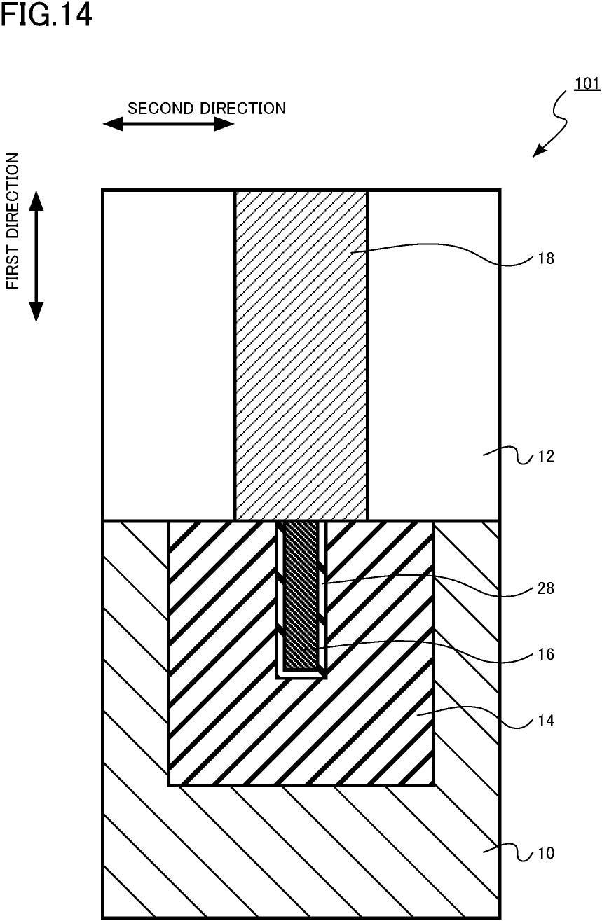

FIG. 14 is a schematic cross-sectional view of a semiconductor device of a modification example of the first embodiment. The semiconductor device of the modification example of the first embodiment includes an insulating structure 101. The insulating structure 101 is a structure for electrically separating a conductive layer and a semiconductor layer from each other. The semiconductor device of the modification example of the first embodiment is different from the semiconductor device according to the first embodiment in that the semiconductor device of the modification example of the first embodiment further includes a fourth insulating layer containing silicon (Si), oxygen (O), and nitrogen (N) between the second insulating layer and the third insulating layer.

In the insulating structure 101, a fourth insulating layer 28 is provided between the second insulating layer 14 and the third insulating layer 16. The fourth insulating layer 28 is in contact with, for example, the second insulating layer 14 and the third insulating layer 16.

The fourth insulating layer 28 contains silicon (Si), oxygen (O), and nitrogen (N). The fourth insulating layer 28 contains, for example, silicon (Si), oxygen (O), and nitrogen (N) as main components. The fact that the fourth insulating layer 28 contains silicon (Si) and oxygen (O) as main components means that, among the elements contained in the fourth insulating layer 28, there is no element having a higher content ratio than silicon (Si), oxygen (O), and nitrogen (N).

The fourth insulating layer 28 contains, for example, silicon oxynitride. The fourth insulating layer 28 is, for example, a silicon oxynitride.

The insulating structure 101 of the comparative example can be manufactured, for example, by forming a silicon oxynitride film in the opening 23 before the aluminum oxide film 25 is formed in the method for manufacturing the insulating structure 100 according to the first embodiment described above.

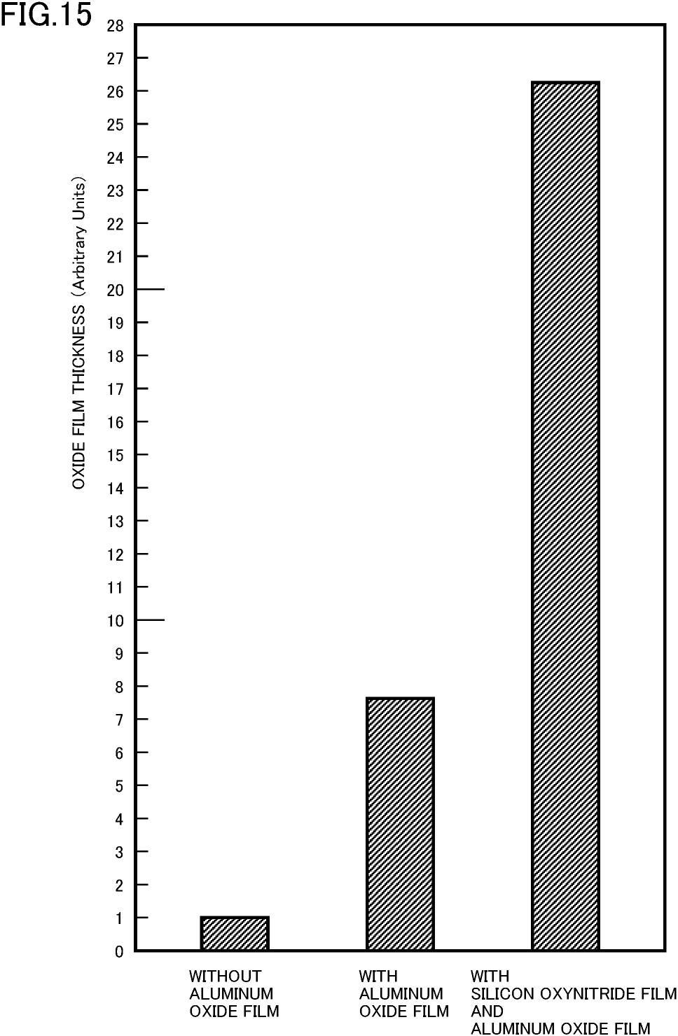

FIG. 15 is an explanatory diagram of the function and effect of a method for manufacturing the semiconductor device of the modification example of the first embodiment. FIG. 15 is a diagram showing the thickness of an oxide film formed by oxidizing the semiconductor layer by radical oxidation.

FIG. 15 is a diagram for comparing the oxide film thickness when a film containing silicon (Si), oxygen (O), and nitrogen (N) and a metal oxide film are formed on the semiconductor layer, the oxide film thickness when only the metal oxide film is formed, and the oxide film thickness when the film containing silicon (Si), oxygen (O), and nitrogen (N) and the metal oxide film are not formed. FIG. 15 shows a case where the semiconductor layer is a single crystal silicon layer, the film containing silicon (Si), oxygen (O), and nitrogen (N) is a silicon oxynitride film, and the metal oxide film is an aluminum oxide film. FIG. 15 shows a case where the thickness of the silicon oxynitride film is 8 nm, the thickness of the aluminum oxide film is 3 nm, and the temperature of radical oxidation is 700° C.

As is apparent from FIG. 15, it can be seen that the oxide film thickness when the silicon oxynitride film and the aluminum oxide film are formed on the semiconductor layer to perform radical oxidation is equal to or more than 26 times the oxide film thickness when the silicon oxynitride film and the aluminum oxide film are not formed. In addition, it can be seen that the oxide film thickness when the silicon oxynitride film and the aluminum oxide film are formed on the semiconductor layer to perform radical oxidation is equal to or more than 3 times the oxide film thickness when only the aluminum oxide film is formed to perform radical oxidation. It can be seen that significantly large accelerated oxidation occurs by forming the silicon oxynitride film and the aluminum oxide film on the semiconductor layer to perform radical oxidation.

The insulating structure 101 of the modification example of the first embodiment including the fourth insulating layer 28 can be easily formed at a low temperature and in a short time. Therefore, for example, even if an element having low heat resistance is formed in the semiconductor device before the insulating structure 101 is formed, degradation of the characteristics of the element due to heat treatment can be further suppressed.

As described above, according to the first embodiment and its modification example, since the insulation between the conductive layer and the semiconductor layer is improved, it is possible to improve the characteristics of the semiconductor device.

### Second Embodiment

A semiconductor memory device according to a second embodiment includes: a first semiconductor layer containing silicon (Si); a first insulating layer provided in a first direction of the first semiconductor layer; a second insulating layer surrounded by the first semiconductor layer in a first cross section perpendicular to the first direction and containing silicon (Si) and oxygen (O); a third insulating layer surrounded by the second insulating layer in the first cross section and containing a metal element and oxygen (O); a conductive layer extending in the first direction, surrounded by the first insulating layer in a second cross section perpendicular to the first direction, provided in the first direction of the third insulating layer, and spaced from the first semiconductor layer; a first gate electrode layer provided in the first direction of the first semiconductor layer and electrically connected to the conductive layer; a second semiconductor layer extending in the first direction; and a charge storage layer provided between the first gate electrode layer and the second semiconductor layer.

The semiconductor memory device according to the second embodiment is a three-dimensional NAND flash memory. A memory cell of the semiconductor memory device according to the second embodiment is a so-called metal-oxide-nitride-oxide-semiconductor type (MONOS type) memory cell.

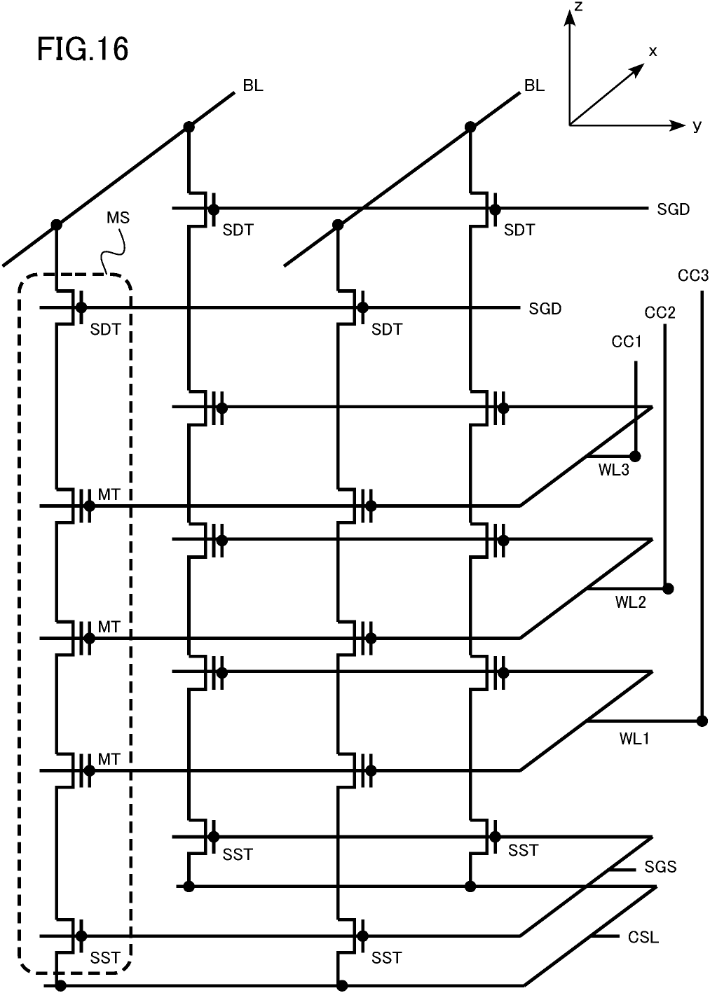

FIG. 16 is a circuit diagram of a main part of the semiconductor memory device according to the second embodiment. FIG. 16 is a circuit diagram including a memory cell array and contact electrodes of a three-dimensional NAND flash memory.

As shown in FIG. 16, the main part of the three-dimensional NAND flash memory according to the second embodiment includes a first word line WL1, a second word line WL2, a third word line WL3, a common source line CSL, a source selection gate line SGS, a plurality of drain selection gate lines SGD, a plurality of bit lines BL, a plurality of memory strings MS, a first contact electrode CC1, a second contact electrode CC2, and a third contact electrode CC3.

Hereinafter, the first word line WL1, the second word line WL2, and the third word line WL3 may be referred to as a word line WL individually or collectively. In addition, the first contact electrode CC1, the second contact electrode CC2, and the third contact electrode CC3 may be referred to as a contact electrode CC individually or collectively.

The plurality of word lines WL are arranged so as to be spaced from each other in the z direction. The plurality of word lines WL are arranged so as to be stacked in the z direction. The plurality of memory strings MS extend in the z direction. The plurality of bit lines BL extend in the x direction, for example.

Hereinafter, the x direction is defined as a third direction, the y direction is defined as a second direction, and the z direction is defined as a first direction. The x direction, the y direction, and the z direction cross each other. For example, the x direction, the y direction, and the z direction are perpendicular to each other.

As shown in FIG. 16, each memory string MS includes a source selection transistor SST, a plurality of memory cells, and a drain selection transistor SDT connected in series to each other between the common source line CSL and the bit line BL. One memory string MS can be selected by selecting one bit line BL and one drain selection gate line SGD, and one memory cell can be selected by selecting one word line WL. The word line WL is a gate electrode of a memory cell transistor MT forming the memory cell. The contact electrode CC is provided to apply a gate voltage to the word line WL.

In addition, although FIG. 16 illustrates a case where one memory string MS includes three memory cells, the number of memory cells included in one memory string MS is not limited to three.

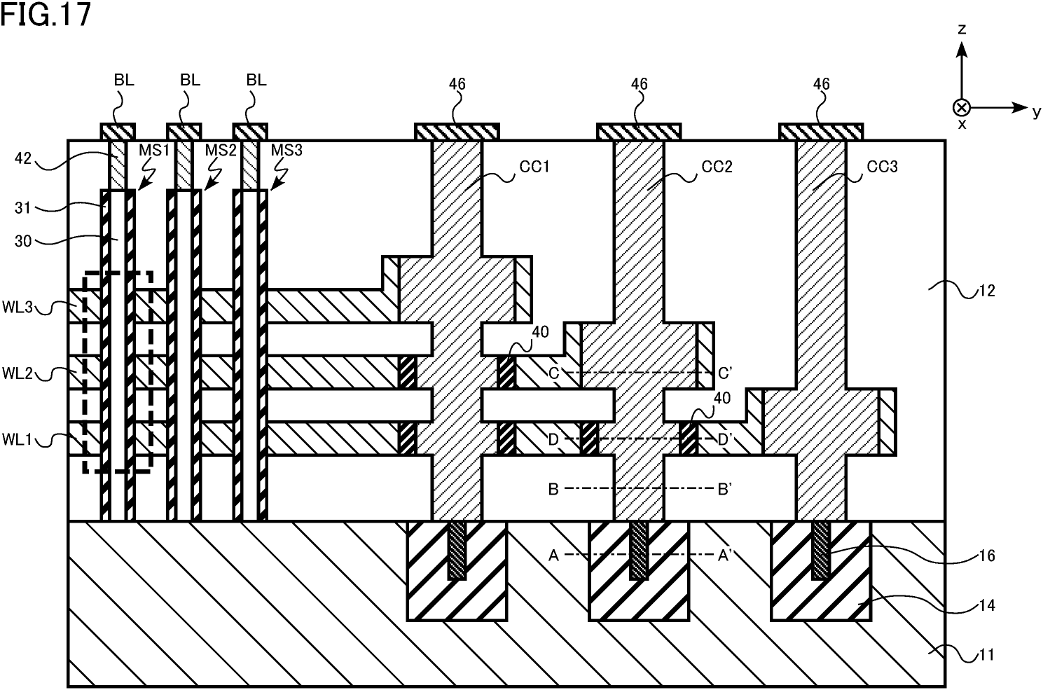

FIG. 17 is a schematic cross-sectional view of the main part of the semiconductor memory device according to the second embodiment. FIG. 17 is a cross-sectional view including a memory cell array and contact electrodes of a three-dimensional NAND flash memory. FIG. 17 is a cross-sectional view corresponding to the circuit diagram of FIG. 16.

The three-dimensional NAND flash memory according to the second embodiment includes a first semiconductor layer 11, a first insulating layer 12, a second insulating layer 14, a third insulating layer 16, a second semiconductor layer 30, a gate insulating layer 31, a separation insulating layer 40, a connection electrode 42, a wiring layer 46, a first memory string MS1, a second memory string MS2, a third memory string MS3, a first word line WL1, a second word line WL2, a third word line WL3, a plurality of bit lines BL, a first contact electrode CC1, a second contact electrode CC2, and a third contact electrode CC3. In FIG. 17, the common source line CSL, the source selection gate line SGS, and the drain selection gate line SGD are not shown.

The second word line WL2 is an example of the first gate electrode layer. The first word line WL1 is an example of the second gate electrode layer. The second contact electrode CC2 is an example of a conductive layer.

The three-dimensional NAND flash memory according to the second embodiment includes the same structure as the insulating structure 100 according to the first embodiment in order to electrically separate the contact electrode CC and the semiconductor layer 10 from each other. Hereinafter, the description of a part of the content overlapping the first embodiment may be omitted.

The first semiconductor layer 11 contains silicon (Si). The first semiconductor layer 11 contains, for example, silicon (Si) as a main component. The first semiconductor layer 11 is, for example, a single crystal silicon layer or a polycrystalline silicon layer.

The first semiconductor layer 11 is not limited to the single crystal silicon layer or the polycrystalline silicon layer. The first semiconductor layer 11 may be, for example, a silicon germanide layer or a silicon carbide layer.

Each of the first memory string MS1, the second memory string MS2, and the third memory string MS3 includes the second semiconductor layer 30 and the gate insulating layer 31. Each of the first memory string MS1, the second memory string MS2, and the third memory string MS3 is electrically connected to the bit line BL by the connection electrode 42.

The first contact electrode CC1, the second contact electrode CC2, and the third contact electrode CC3 extend in the z direction. The first contact electrode CC1, the second contact electrode CC2, and the third contact electrode CC3 are conductors.

The first contact electrode CC1, the second contact electrode CC2, and the third contact electrode CC3 are, for example, a metal, a metal compound, or a semiconductor. The first contact electrode CC1, the second contact electrode CC2, and the third contact electrode CC3 contain, for example, tungsten (W), molybdenum (Mo), ruthenium (Ru), or titanium (Ti). The first contact electrode CC1, the second contact electrode CC2, and the third contact electrode CC3 are, for example, polycrystalline silicon.

The first contact electrode CC1 is electrically connected to the third word line WL3. The first contact electrode CC1 is in contact with the third word line WL3.

The first contact electrode CC1 is electrically separated from the second word line WL2. The first contact electrode CC1 is spaced from the second word line WL2. The separation insulating layer 40 is provided between the first contact electrode CC1 and the second word line WL2.

The first contact electrode CC1 is electrically separated from the first word line WL1. The first contact electrode CC1 is spaced from the first word line WL1. The separation insulating layer 40 is provided between the first contact electrode CC1 and the first word line WL1.

The second contact electrode CC2 is electrically connected to the second word line WL2. The second contact electrode CC2 is in contact with the second word line WL2.

The second contact electrode CC2 is electrically separated from the first word line WL1. The second contact electrode CC2 is spaced from the first word line WL1. The separation insulating layer 40 is provided between the second contact electrode CC2 and the first word line WL1.

The third contact electrode CC3 is electrically connected to the first word line WL1. The third contact electrode CC3 is in contact with the first word line WL1.

The separation insulating layer 40 is, for example, an oxide. The separation insulating layer 40 is, for example, a silicon oxide.

Each of the first contact electrode CC1, the second contact electrode CC2, and the third contact electrode CC3 is electrically connected to the wiring layer 46. A gate voltage for controlling the memory cell transistor MT is applied to the wiring layer 46.

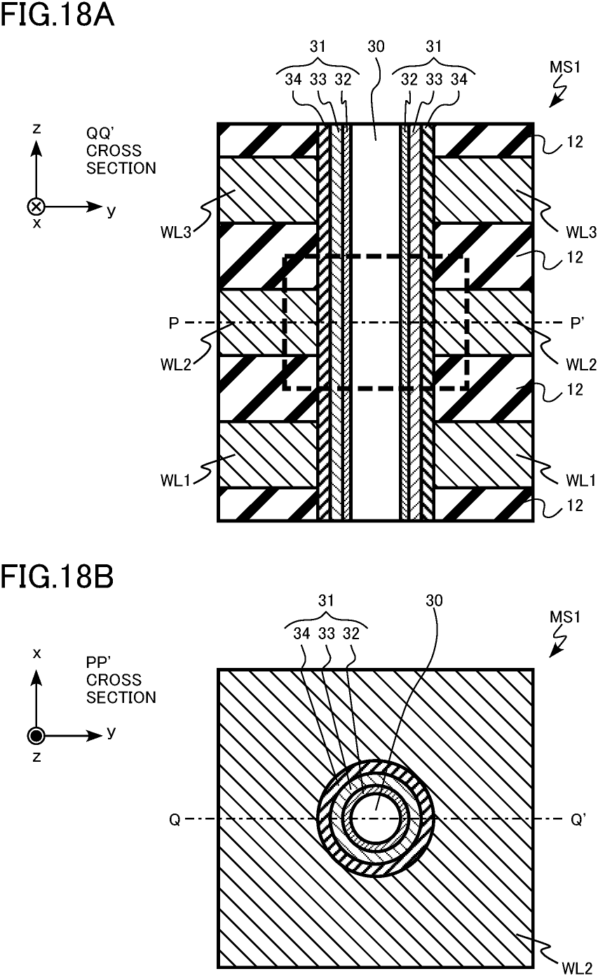

FIGS. 18A and 18B are schematic cross-sectional views of a memory cell array of the semiconductor memory device according to the second embodiment. FIGS. 18A and 18B show cross sections of a plurality of memory cells, for example, in the first memory string MS1 surrounded by the dotted line in the memory cell array of FIG. 17.

FIG. 18A is a yz cross-sectional view of the first memory string MS1. FIG. 18A is a cross-sectional view taken along the line QQ′ of FIG. 18B. FIG. 18B is an xy cross-sectional view of the first memory string MS1. FIG. 18B is a cross-sectional view taken along the line PP′ of FIG. 18A. In FIG. 18A, the region surrounded by the dotted line is one memory cell.

The word line WL and the first insulating layer 12 are alternately stacked in the z direction. The word line WL and the first insulating layer 12 are provided in the z direction of the first semiconductor layer 11. The word line WL is spaced from the first semiconductor layer 11 in the z direction. The first insulating layer 12 electrically separates the word line WL and the word line WL from each other.

The second semiconductor layer 30 extends in the z direction. The second semiconductor layer 30 extends in a direction perpendicular to the surface of the first semiconductor layer 11. The second semiconductor layer 30 penetrates the word line WL and the first insulating layer 12. The second semiconductor layer 30 is in contact with, for example, the first semiconductor layer 11.

The second semiconductor layer 30 is surrounded by the word line WL. The second semiconductor layer 30 has, for example, a columnar shape. The second semiconductor layer 30 functions as a channel of the memory cell transistor MT.

The second semiconductor layer 30 is, for example, a polycrystalline semiconductor. The second semiconductor layer 30 is, for example, polycrystalline silicon.

The gate insulating layer 31 is provided between the word line WL and the second semiconductor layer 30. The gate insulating layer 31 is provided between the first word line WL1 and the second semiconductor layer 30. The gate insulating layer 31 is provided between the second word line WL2 and the second semiconductor layer 30. The gate insulating layer 31 is provided between the third word line WL3 and the second semiconductor layer 30.

The gate insulating layer 31 includes a tunnel insulating layer 32, a charge storage layer 33, and a block insulating layer 34.

The tunnel insulating layer 32 is provided between the second semiconductor layer 30 and the word line WL. The tunnel insulating layer 32 has a function of allowing a charge to pass therethrough according to a voltage applied between the word line WL and the second semiconductor layer 30. The tunnel insulating layer 32 contains, for example, oxide, nitride, or oxynitride. The tunnel insulating layer 32 has, for example, a stacked structure of silicon oxide and silicon nitride.

The charge storage layer 33 is provided between the tunnel insulating layer 32 and the word line WL. The charge storage layer 33 is provided between the tunnel insulating layer 32 and the block insulating layer 34.

The charge storage layer 33 has a function of trapping and storing a charge. The charge is, for example, an electron. The threshold voltage of the memory cell transistor MT changes according to the amount of charge stored in the charge storage layer 33. By using the threshold voltage change, one memory cell can store data.

The charge storage layer 33 contains, for example, nitride. The charge storage layer 33 contains, for example, silicon nitride.

The block insulating layer 34 is provided between the charge storage layer 33 and the word line WL. The block insulating layer 34 has a function of blocking the current flowing between the charge storage layer 33 and the word line WL.

The block insulating layer 34 contains, for example, oxide, acid nitride, or nitride. The block insulating layer 34 contains, for example, aluminum oxide or silicon oxide.

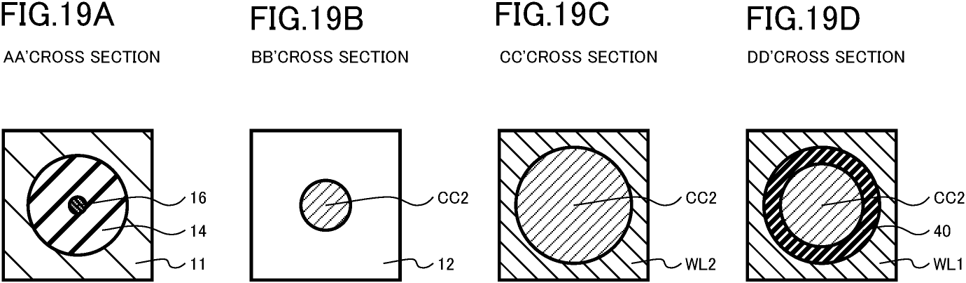

FIGS. 19A, 19B, 19C, and 19D are schematic cross-sectional views of the semiconductor memory device according to the second embodiment. FIG. 19A is a cross-sectional view taken along the line AA′ of FIG. 17. FIG. 19B is a cross-sectional view taken along the line BB′ of FIG. 17. FIG. 19C is a cross-sectional view taken along the line CC′ of FIG. 17. FIG. 19D is a cross-sectional view taken along the line DD′ of FIG. 17.

The first insulating layer 12 is provided in the first direction of the first semiconductor layer 11. The first insulating layer 12 is provided on, for example, the first semiconductor layer 11. The first insulating layer 12 is in contact with, for example, the first semiconductor layer 11.

The first insulating layer 12 contains, for example, oxide. The first insulating layer 12 contains, for example, silicon (Si) and oxygen (O). The first insulating layer 12 contains, for example, silicon oxide. The first insulating layer 12 is, for example, a silicon oxide.

The first insulating layer 12 contains, for example, nitride. The first insulating layer 12 contains, for example, silicon (Si) and nitrogen (N). The first insulating layer 12 contains, for example, silicon nitride. The first insulating layer 12 is, for example, a silicon nitride.

The first insulating layer 12 contains, for example, oxynitride. The first insulating layer 12 contains, for example, silicon (Si), oxygen (O), and nitrogen (N). The first insulating layer 12 contains, for example, silicon oxynitride. The first insulating layer 12 is, for example, a silicon oxynitride.

The second insulating layer 14 is surrounded by the first semiconductor layer 11 in the first cross section perpendicular to the first direction. For example, as shown in FIG. 19A, the second insulating layer 14 is surrounded by the first semiconductor layer 11 in the AA′ cross section. The second insulating layer 14 is in contact with, for example, the first semiconductor layer 11.

The second insulating layer 14 contains silicon (Si) and oxygen (O). The second insulating layer 14 contains, for example, silicon (Si) and oxygen (O) as main components. The fact that the second insulating layer 14 contains silicon (Si) and oxygen (O) as main components means that, among the elements contained in the second insulating layer 14, there is no element having a higher content ratio than silicon (Si) and oxygen (O).

The second insulating layer 14 contains, for example, silicon oxide. The second insulating layer 14 is, for example, a silicon oxide.

The third insulating layer 16 is surrounded by the second insulating layer 14 in the first cross section perpendicular to the first direction. For example, as shown in FIG. 19A, the third insulating layer 16 is surrounded by the second insulating layer 14 in the AA′ cross section. The third insulating layer 16 is spaced from, for example, the first semiconductor layer 11.

The third insulating layer 16 is provided in the first direction of the contact electrode CC. The third insulating layer 16 is provided under the contact electrode CC. The third insulating layer 16 is provided directly under the contact electrode CC.

The third insulating layer 16 contains a metal element and oxygen (O). The metal element contained in the third insulating layer 16 is, for example, at least one metal element selected from the group consisting of aluminum (Al), hafnium (Hf), zirconium (Zr), lanthanum (La), yttrium (Y), titanium (Ti), nickel (Ni), zinc (Zn), indium (In), tin (Sn), gallium (Ga), and tungsten (W).

The third insulating layer 16 contains, for example, the above-described metal element and oxygen (O) as main components. The fact that the third insulating layer 16 contains the above-described metal element and oxygen (O) as main components means that, among the elements contained in the third insulating layer 16, there is no element having a higher content ratio than the above-described metal element and oxygen (O).

The third insulating layer 16 contains, for example, metal oxide. The third insulating layer 16 contains, for example, oxide of the above-described metal element.

The third insulating layer 16 contains, for example, aluminum oxide, hafnium oxide, zirconium oxide, lanthanum oxide, yttrium oxide, titanium oxide, nickel oxide, zinc oxide, indium oxide, tin oxide, gallium oxide, or tungsten oxide. The third insulating layer 16 is, for example, an aluminum oxide, a hafnium oxide, a zirconium oxide, a lanthanum oxide, an yttrium oxide, a titanium oxide, a nickel oxide, a zinc oxide, an indium oxide, a tin oxide, a gallium oxide, or a tungsten oxide.

The chemical composition of the third insulating layer 16 is different from, for example, the chemical composition of the second insulating layer 14. The dielectric constant of the third insulating layer 16 is, for example, higher than the dielectric constant of the second insulating layer 14.

The width of the third insulating layer 16 in the second direction is, for example, equal to or more than 2 nm and equal to or less than 10 nm. The width of the second insulating layer 14 in the second direction is, for example, equal to or more than 3 times and equal to or less than 20 times the width of the third insulating layer 16 in the second direction.

The contact electrode CC is surrounded by the first insulating layer 12 in the second cross section perpendicular to the first direction. For example, as shown in FIG. 19B, the contact electrode CC is surrounded by the first insulating layer 12 in the BB′ cross section. The contact electrode CC is in contact with, for example, the first insulating layer 12.

The contact electrode CC is provided in the first direction of the third insulating layer 16. The contact electrode CC is in contact with, for example, the third insulating layer 16. The contact electrode CC is in contact with, for example, the second insulating layer 14.

The width of the contact electrode CC in the second direction is smaller than, for example, the width of the second insulating layer 14 in the second direction.

The second contact electrode CC2 is surrounded by the second word line WL2 in the third cross section perpendicular to the first direction. For example, as shown in FIG. 19C, the second contact electrode CC2 is surrounded by the second word line WL2 in the CC′ cross section. The second contact electrode CC2 is in contact with the second word line WL2.

The second contact electrode CC2 is surrounded by the first word line WL1 in the fourth cross section perpendicular to the first direction. For example, as shown in FIG. 19D, the second contact electrode CC2 is surrounded by the first word line WL1 in the DD′ cross section.

The second contact electrode CC2 is spaced from the first word line WL1. The second contact electrode CC2 is surrounded by the separation insulating layer 40. The separation insulating layer 40 is provided between the second contact electrode CC2 and the first word line WL1.

Next, an example of a method for manufacturing the semiconductor memory device according to the second embodiment will be described.

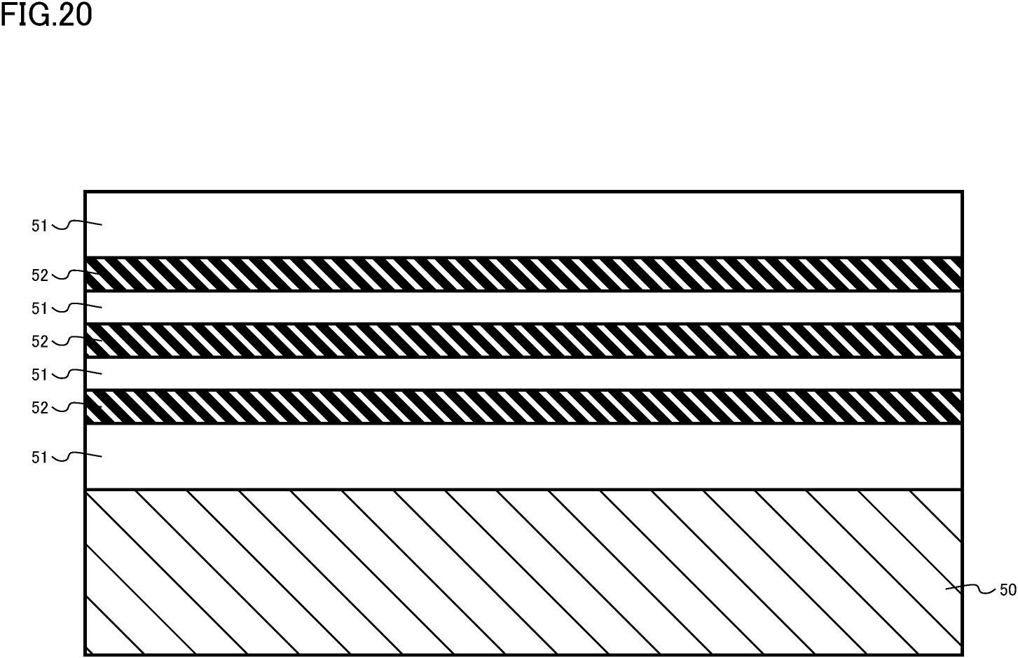

FIGS. 20 to 40 are explanatory diagrams of the method for manufacturing the semiconductor memory device according to the second embodiment. FIGS. 20 to 40 are cross-sectional views corresponding to FIG. 17.

Hereinafter, a case where the first semiconductor layer 11 is single crystal silicon, the first insulating layer 12 is a silicon oxide, the second insulating layer 14 is a silicon oxide, the third insulating layer 16 is an aluminum oxide, and the contact electrode CC is tungsten (W) will be described as an example.

First, a first silicon oxide film 51 and a first silicon nitride film 52 are alternately formed on a single crystal silicon layer 50 (FIG. 20). The first silicon oxide film 51 and the first silicon nitride film 52 are formed by using, for example, a CVD method.

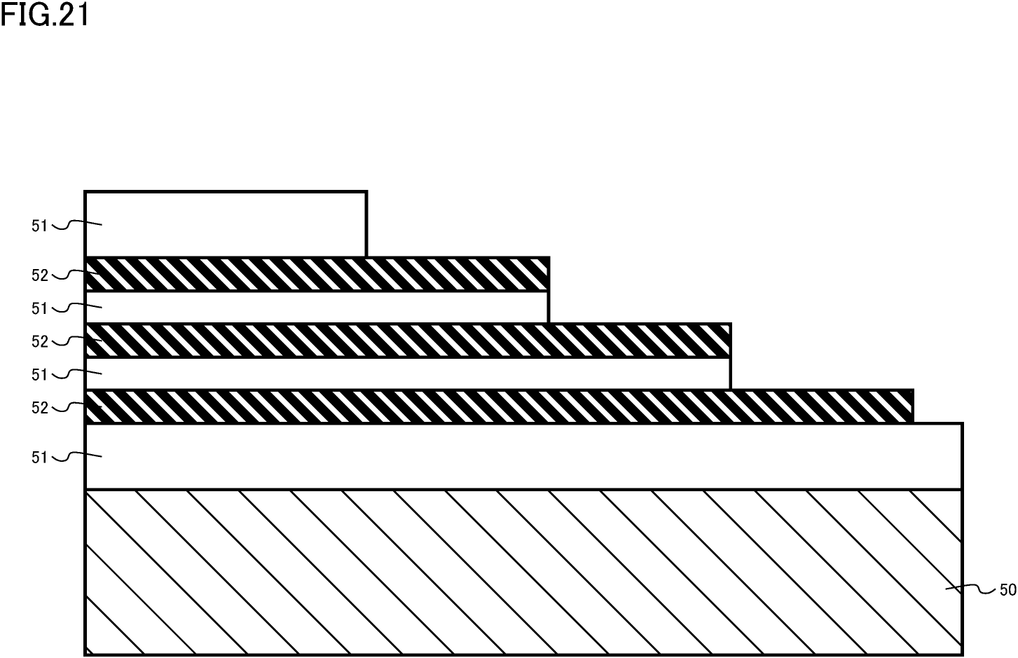

Then, a stepped structure is formed on the first silicon oxide film 51 and the first silicon nitride film 52 (FIG. 21). The stepped structure can be formed, for example, by repeating etching of the first silicon oxide film 51 or the first silicon nitride film 52 and isotropic removal of the resist film after patterning the resist film.

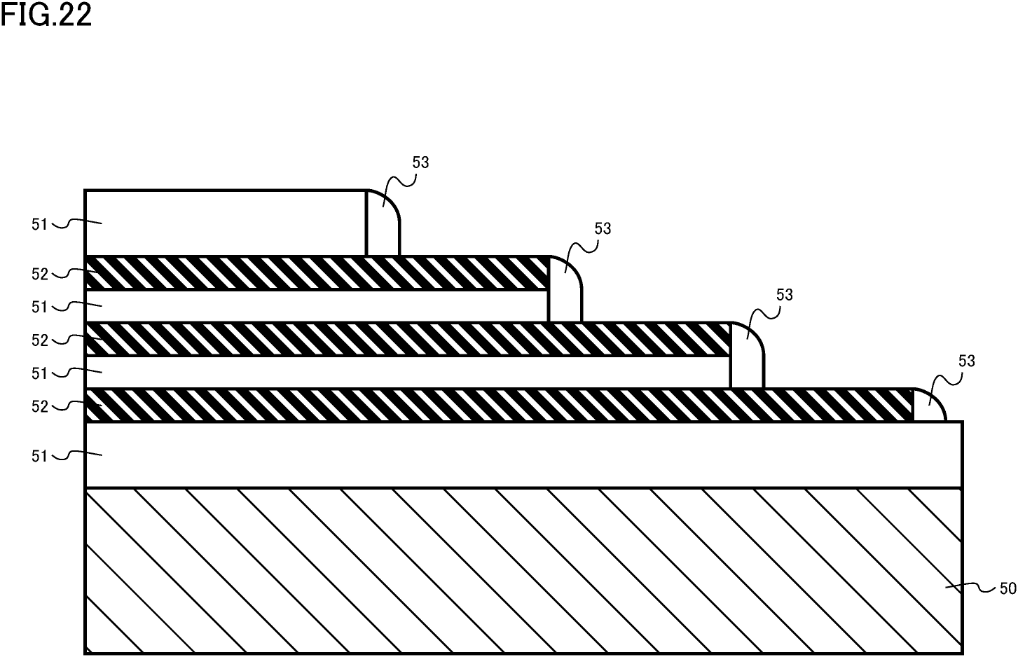

Then, a sidewall insulating film 53 is formed on the side surfaces of the first silicon oxide film 51 and the first silicon nitride film 52 (FIG. 22). The sidewall insulating film 53 can be formed, for example, by the deposition of an insulating film using a CVD method and an RIE method. The sidewall insulating film 53 is, for example, a silicon oxide.

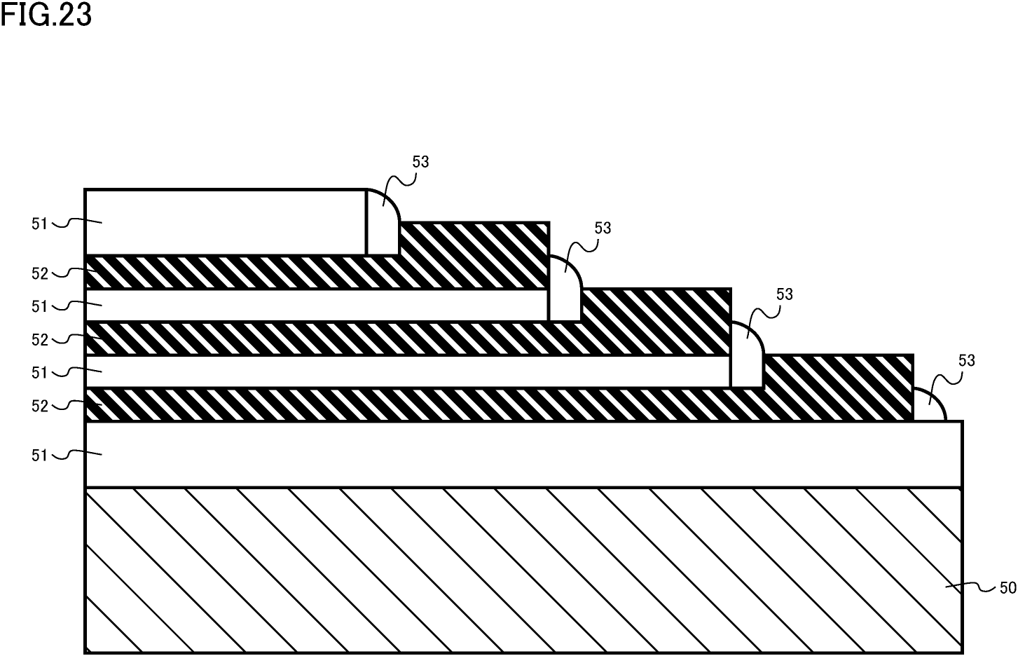

Then, a silicon nitride film is selectively formed on the surface of the exposed first silicon nitride film 52 (FIG. 23). The silicon nitride film is formed by using, for example, a CVD method.

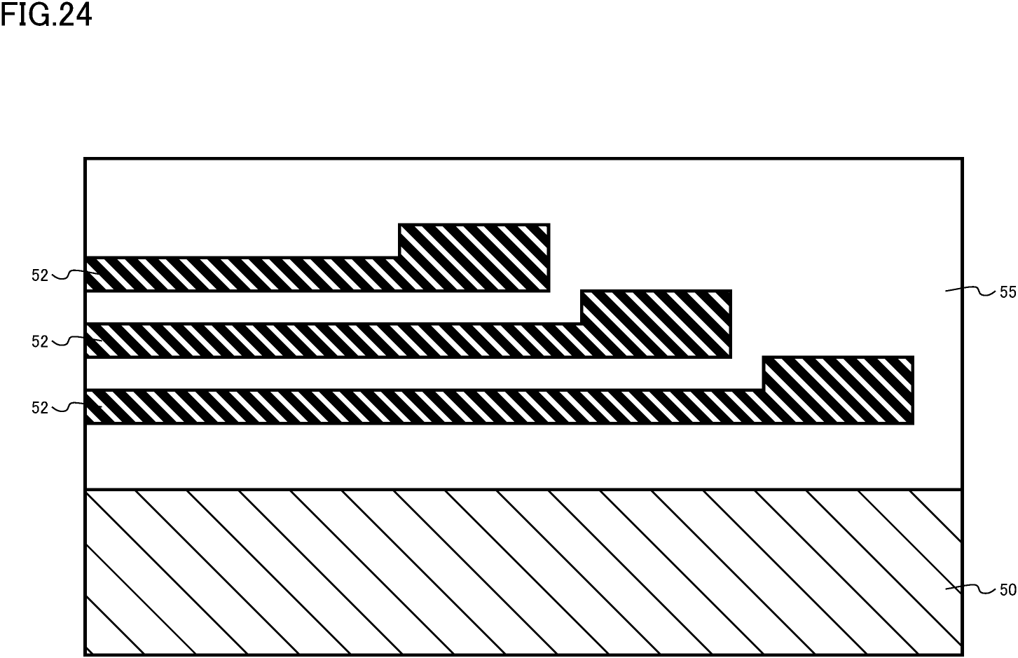

Then, a silicon oxide film is formed on the first silicon nitride film 52, and a silicon oxide layer 55 including the first silicon oxide film 51 is formed (FIG. 24). The silicon oxide layer 55 finally becomes the first insulating layer 12. The silicon oxide film is formed by using, for example, a CVD method.

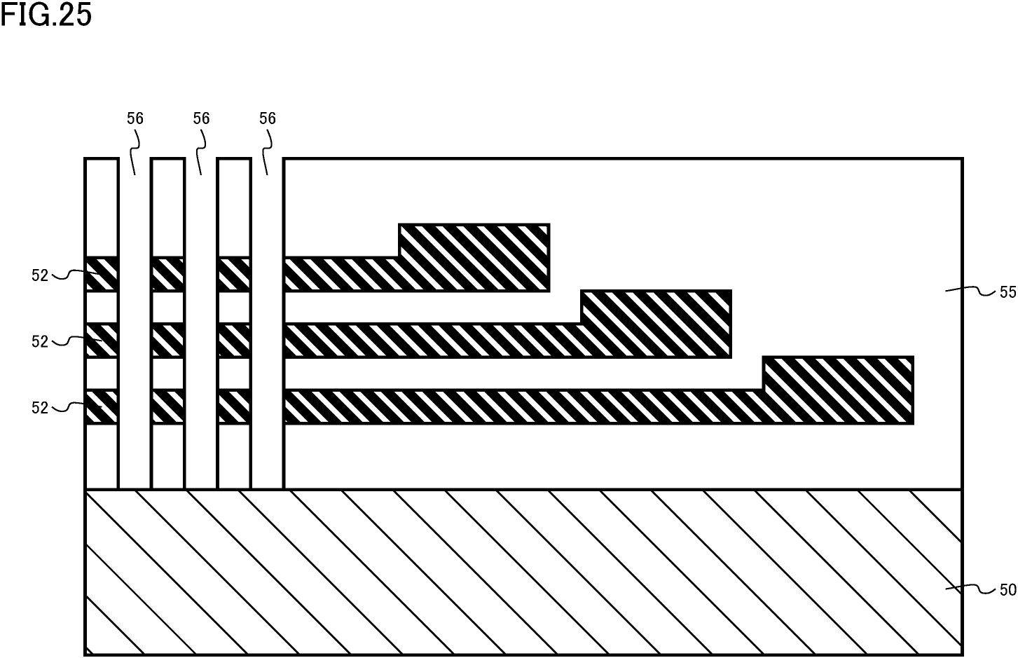

Then, a first opening 56 penetrating the silicon oxide layer 55 and the first silicon nitride film 52 is formed (FIG. 25). The first opening 56 is formed by using, for example, a photolithography method and an RIE method.

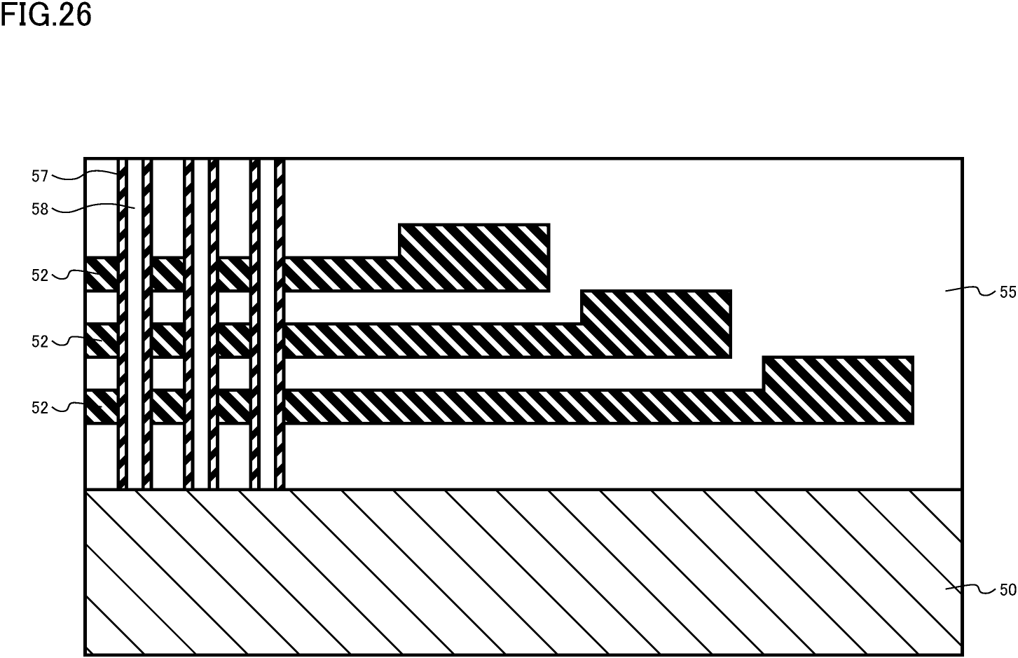

Then, a first insulating film 57 and a polycrystalline silicon film 58 are formed in the first opening 56 (FIG. 26). The first insulating film 57 finally becomes the gate insulating layer 31. In addition, the polycrystalline silicon film 58 finally becomes the second semiconductor layer 30. The first insulating film 57 and the polycrystalline silicon film 58 are formed by using, for example, a CVD method.

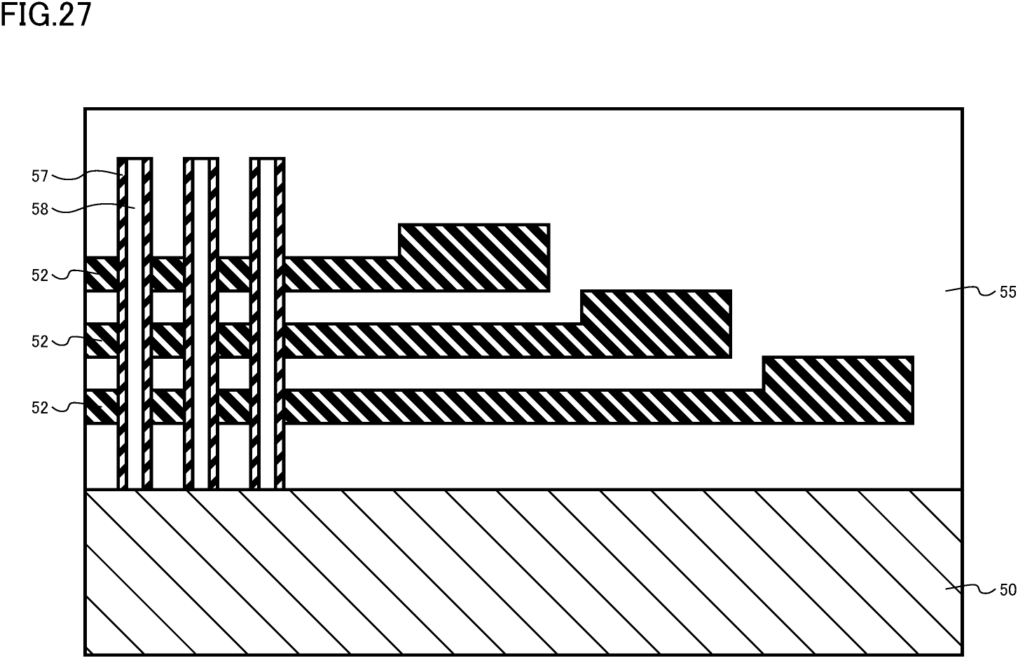

Then, a silicon oxide film is formed on the first insulating film 57 and the polycrystalline silicon film 58 (FIG. 27). The formed silicon oxide film becomes a part of the silicon oxide layer 55. The silicon oxide film is formed by using, for example, a CVD method.

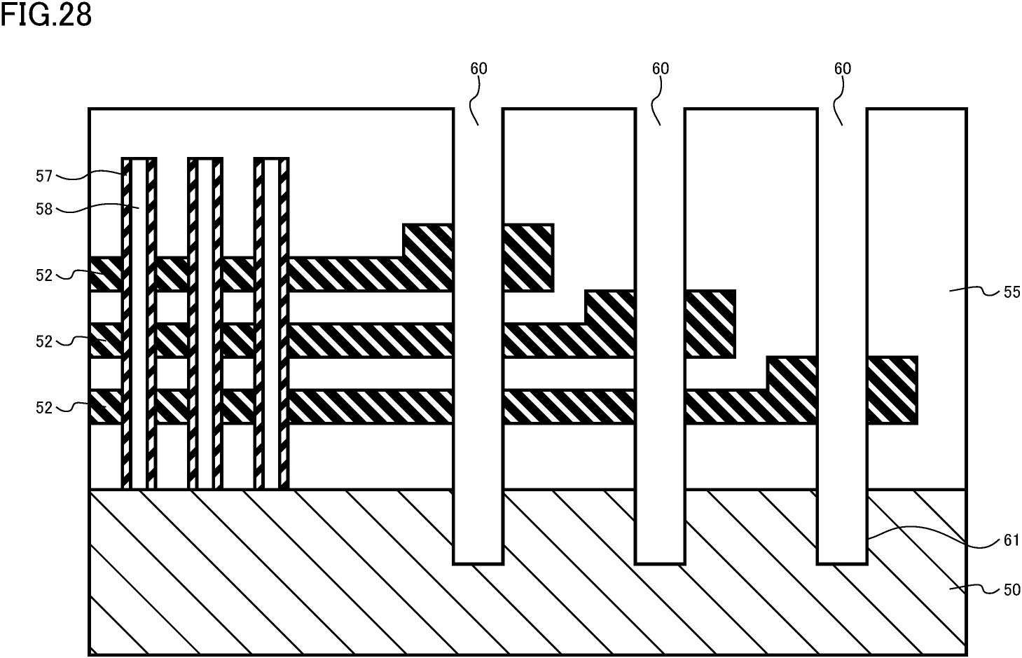

Then, a second opening 60 is formed (FIG. 28). The second opening 60 penetrates the silicon oxide layer 55 and the first silicon nitride film 52. The second opening 60 forms a recess 61 in the single crystal silicon layer 50. The second opening 60 is formed by using, for example, an RIE method. As an etching mask, for example, a hard mask is applied.

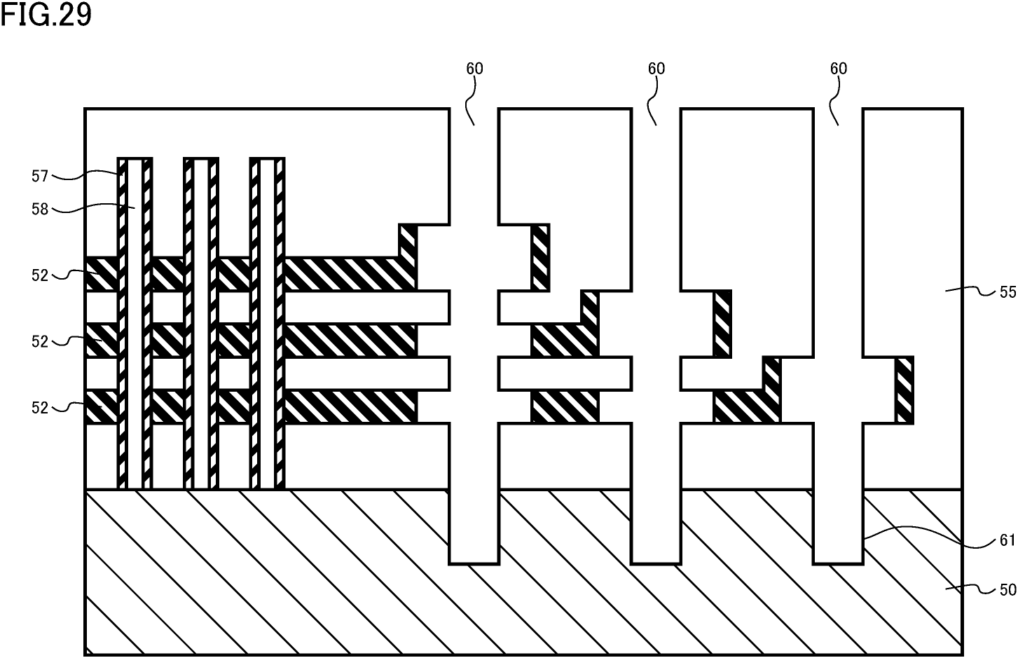

Then, the first silicon nitride film 52 exposed on the inner surface of the second opening 60 is retracted (FIG. 29). The first silicon nitride film 52 is retracted by, for example, isotropic dry etching.

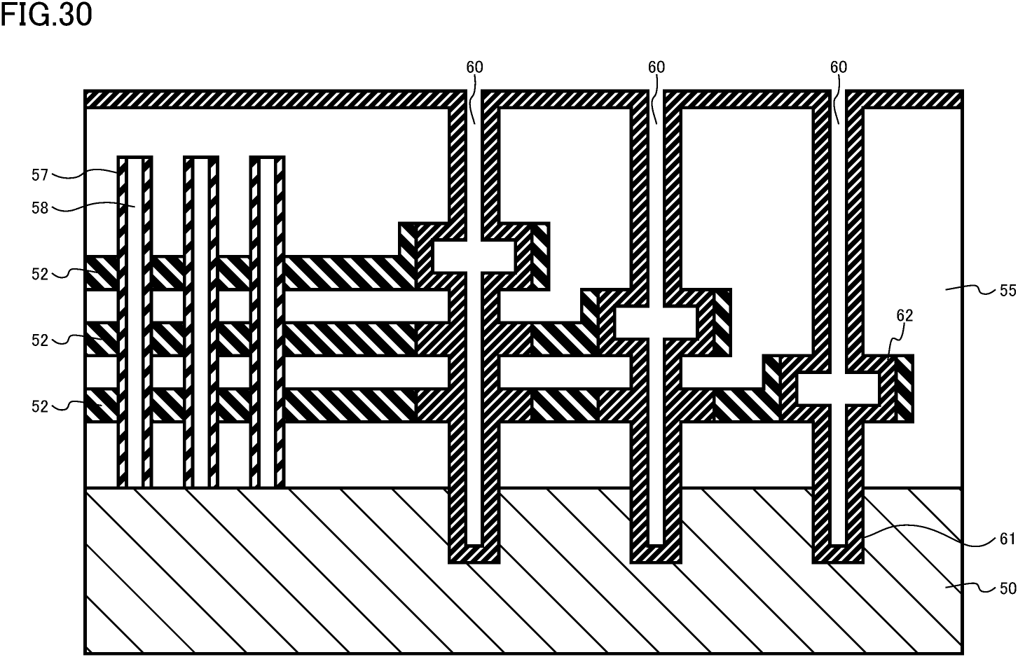

Then, a second silicon oxide film 62 is formed inside the second opening 60 (FIG. 30). The second silicon oxide film 62 is formed by using, for example, a CVD method.

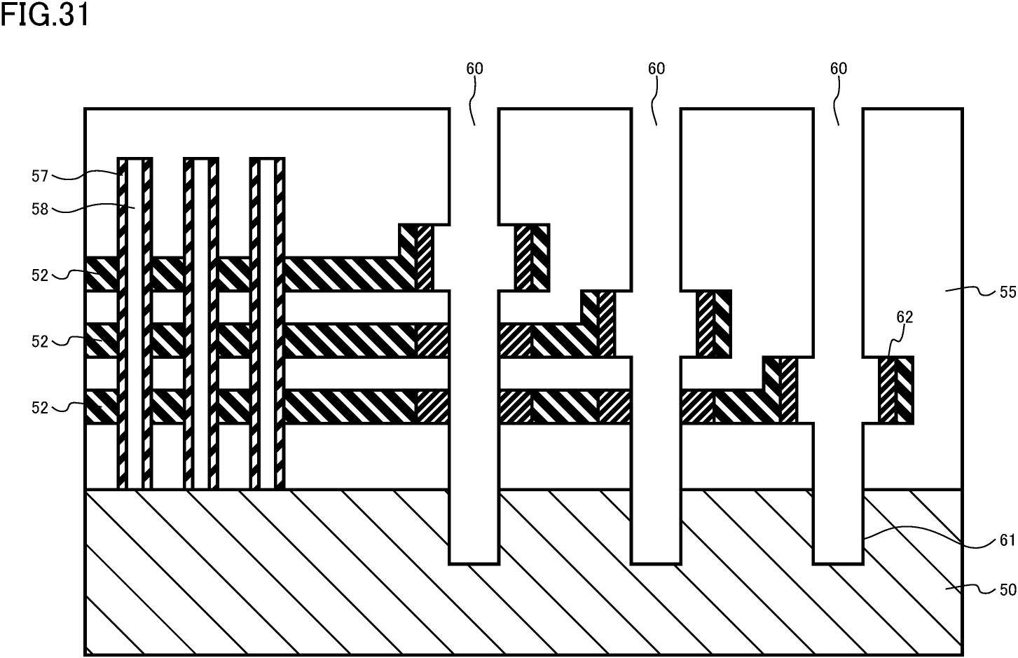

Then, a part of the second silicon oxide film 62 in the second opening 60 is removed (FIG. 31). The second silicon oxide film 62 is removed by using, for example, a wet etching method.

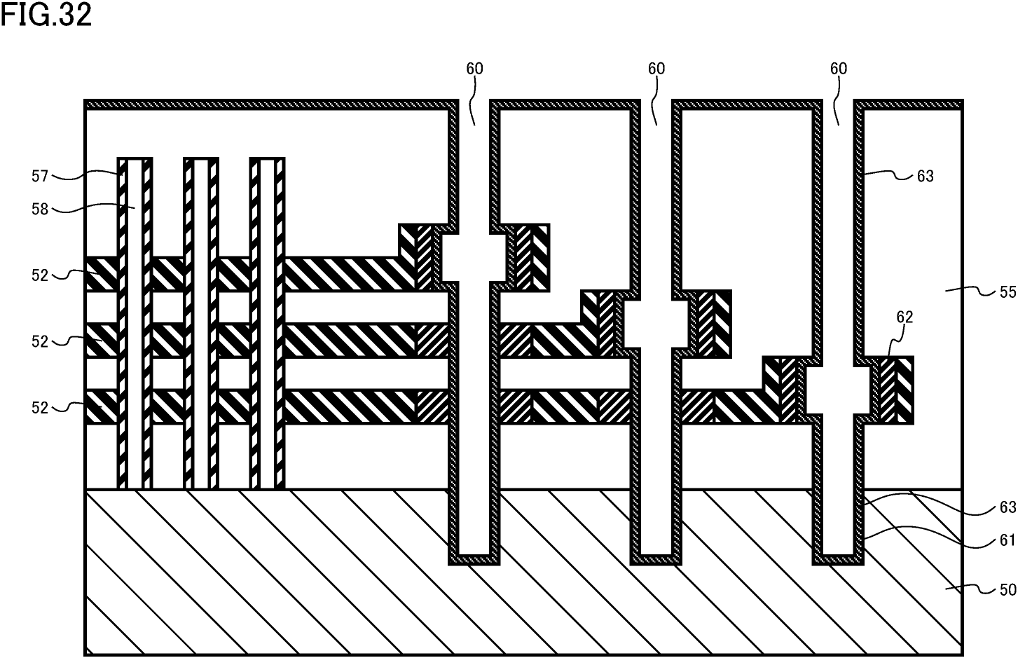

Then, an aluminum oxide film 63 is formed in the second opening 60 (FIG. 32). The aluminum oxide film 63 is formed by using, for example, an ALD method. The thickness of the aluminum oxide film 63 is, for example, equal to or more than 1 nm and equal to or less than 5 nm. A part of the aluminum oxide film 63 finally becomes the third insulating layer 16.

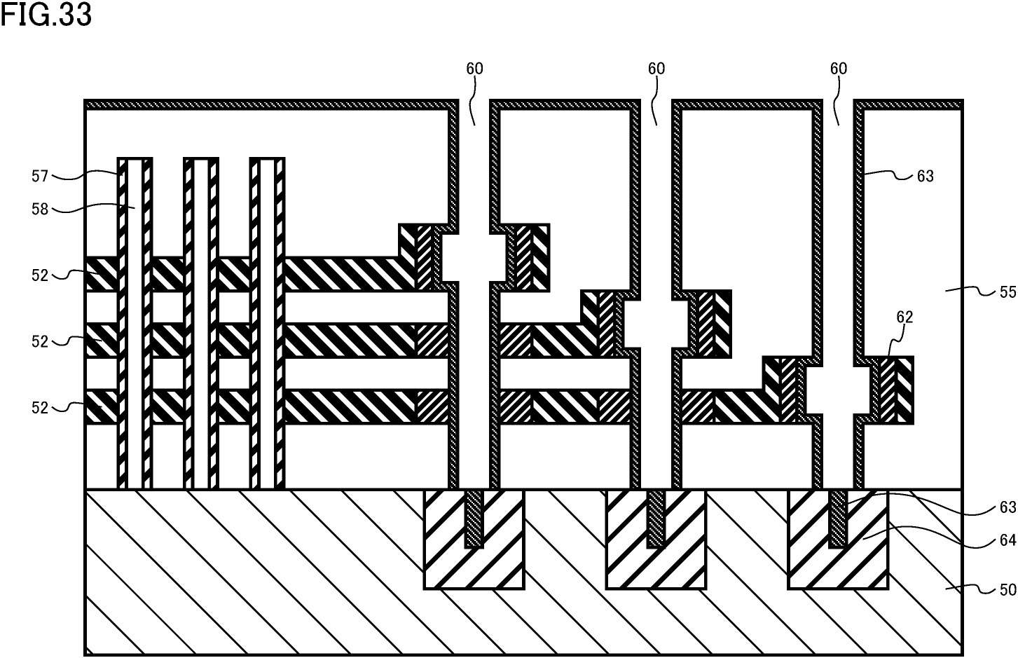

Then, a third silicon oxide film 64 is formed between the single crystal silicon layer 50 and the aluminum oxide film 63 by using radical oxidation (FIG. 33). By oxidizing the single crystal silicon layer 50 by radical oxidation, the third silicon oxide film 64 is formed. The third silicon oxide film 64 finally becomes the second insulating layer 14.

Radical oxidation is performed in an atmosphere containing oxygen radicals or hydroxyl radicals. For example, radical oxidation is performed in an atmosphere in which oxygen gas, hydrogen gas, and argon gas are turned into plasma. For example, radical oxidation is performed in an atmosphere in which water vapor is turned into plasma.

The method for generating oxygen radicals or hydroxyl radicals used for radical oxidation is not particularly limited. Oxygen radicals or hydroxyl radicals are generated by using, for example, an inductively coupled plasma method, a microwave plasma method, an electron cyclotron resonance method, a helicon wave method, or a thermal filament method.

The temperature of radical oxidation is, for example, equal to or more than 300° C. and equal to or less than 900° C. The pressure of radical oxidation is, for example, equal to or more than 50 Pa and equal to or less than 3000 Pa.

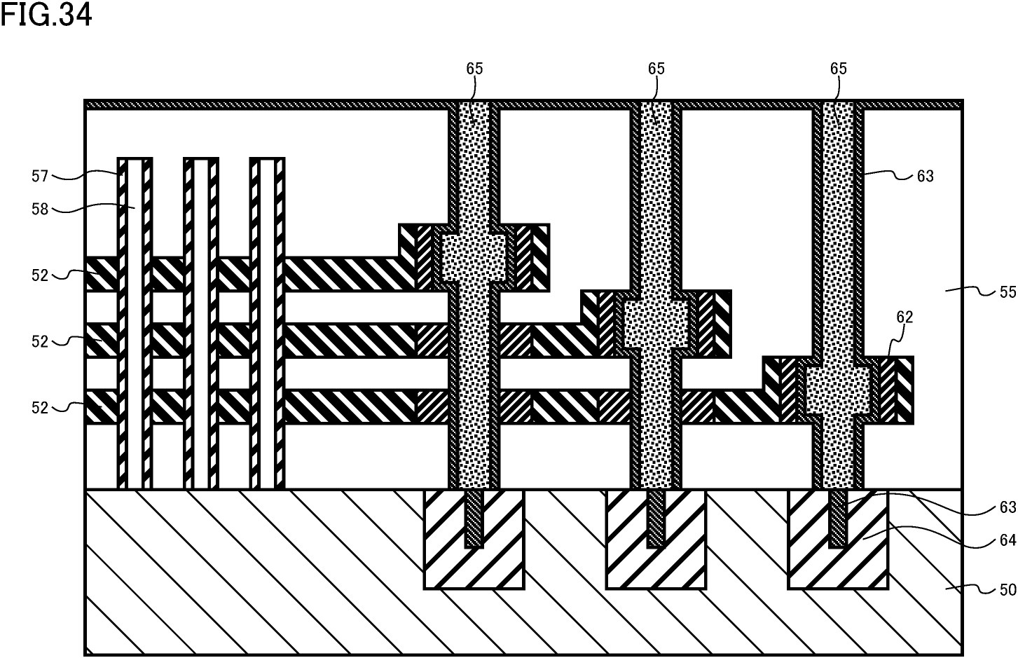

Then, the inside of the second opening 60 is buried with an amorphous silicon film 65 (FIG. 34). The amorphous silicon film 65 is formed by using, for example, a CVD method.

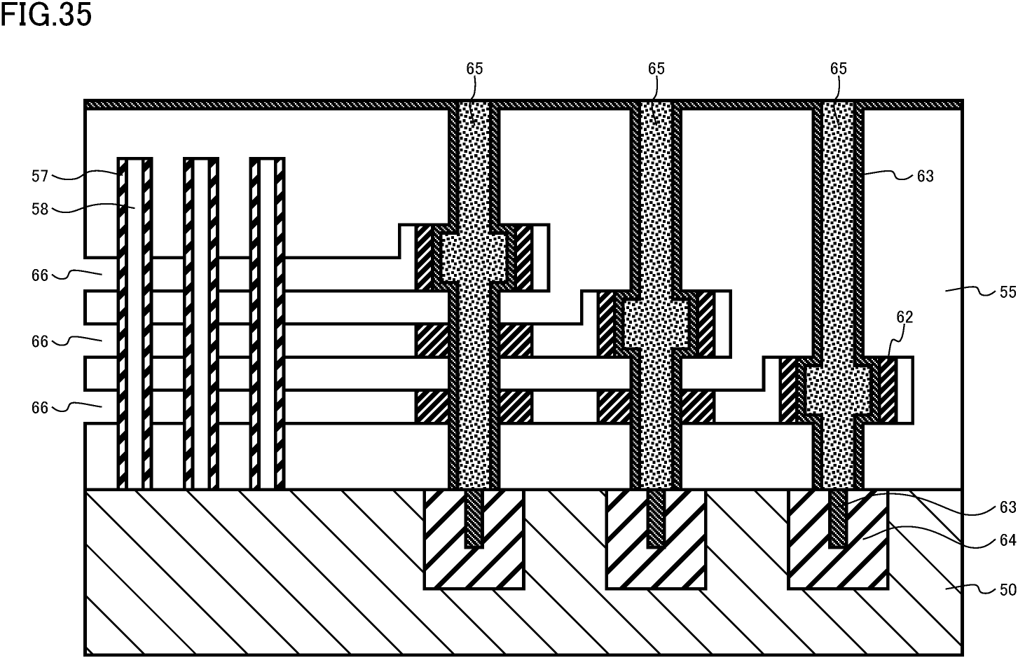

Then, the first silicon nitride film 52 is removed (FIG. 35). The first silicon nitride film 52 is selectively removed with respect to the silicon oxide layer 55 and the second silicon oxide film 62. The first silicon nitride film 52 is removed by using, for example, a wet etching method in which a wet etching solution is supplied from an opening (not shown). A void 66 is formed in a portion where the first silicon nitride film 52 is removed.

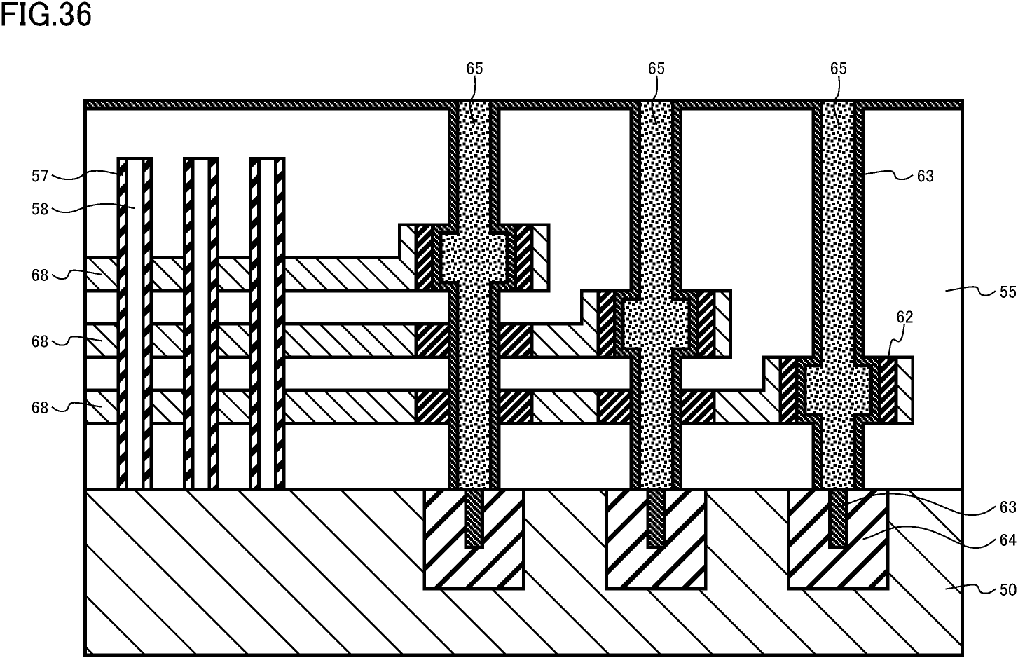

Then, a first tungsten film 68 is formed in the void 66 (FIG. 36). The first tungsten film 68 is formed by using a CVD method. The first tungsten film 68 finally becomes the word line WL.

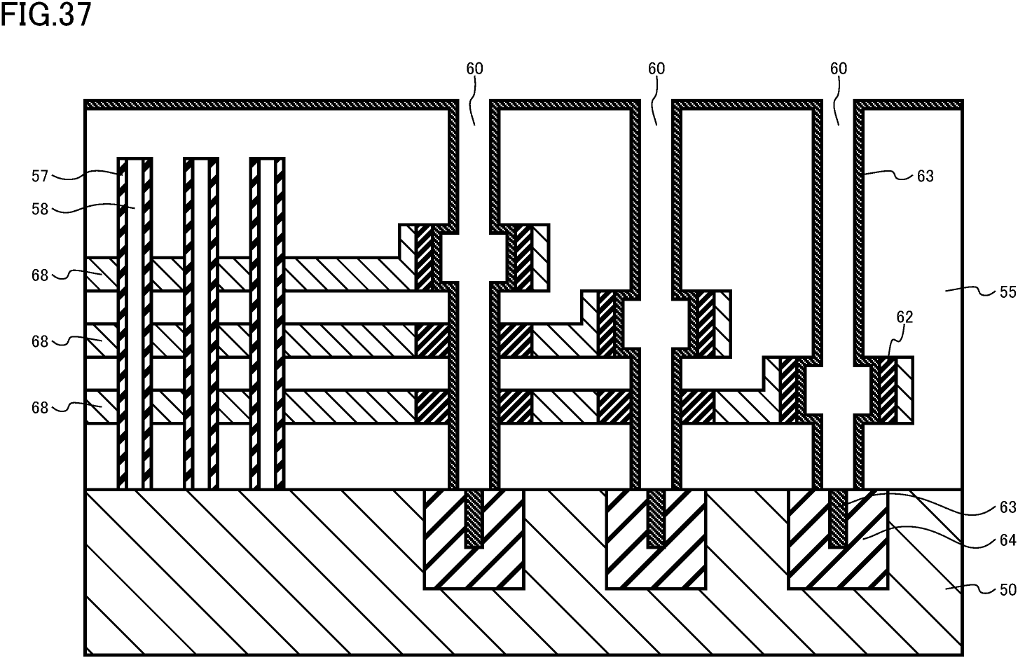

Then, the amorphous silicon film 65 formed in the second opening 60 is removed (FIG. 37). The amorphous silicon film 65 is removed by using, for example, a wet etching method.

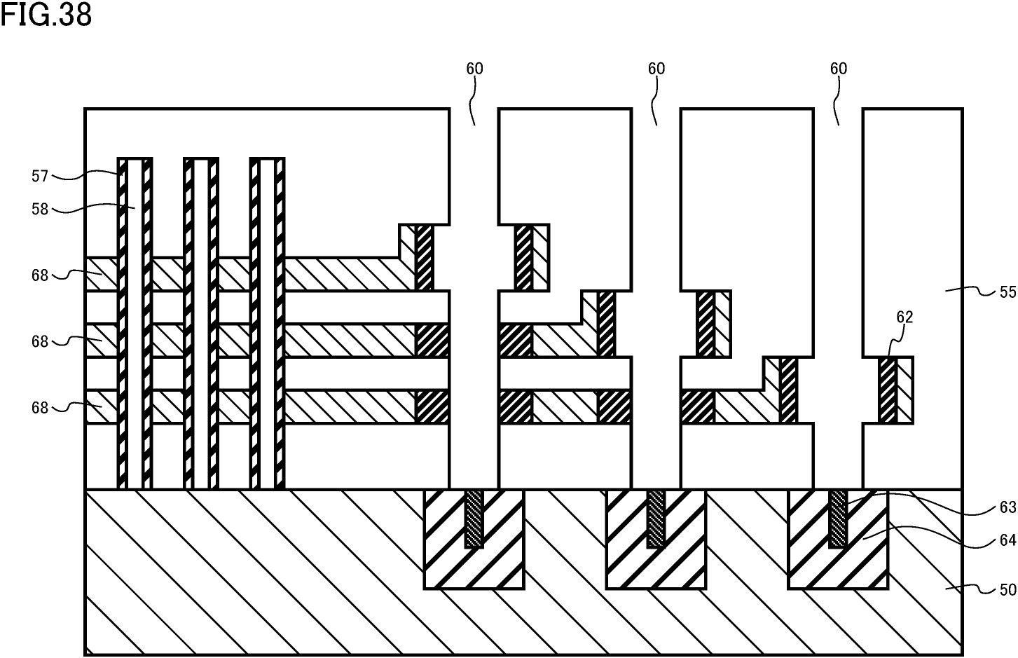

Then, the aluminum oxide film 63 formed in the second opening 60 is removed (FIG. 38). The aluminum oxide film 63 is removed by using, for example, a wet etching method.

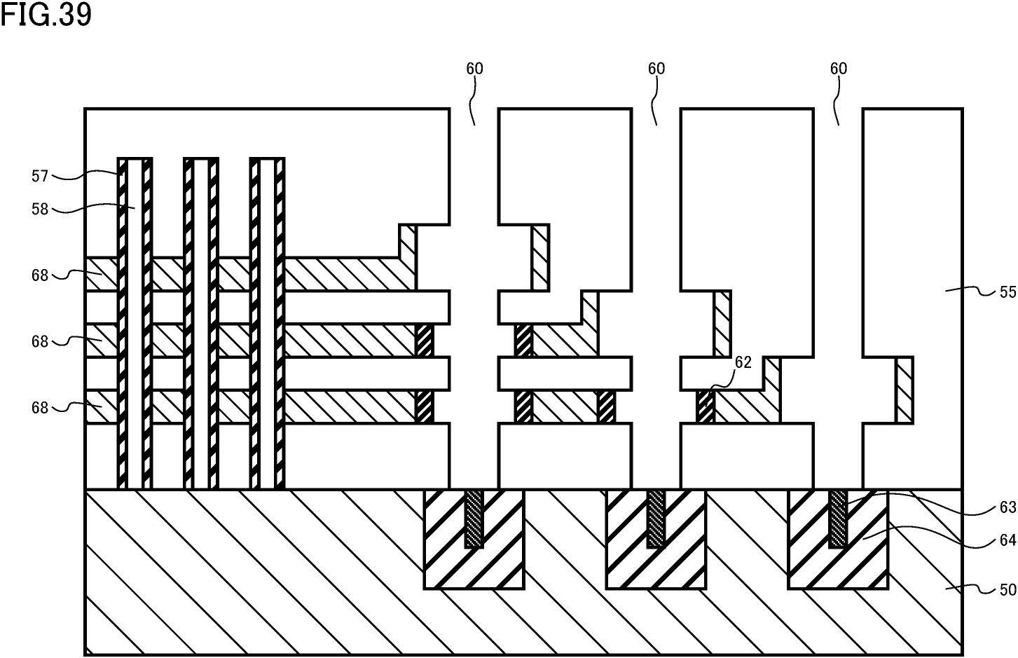

Then, a part of the second silicon oxide film 62 formed in the second opening 60 is removed (FIG. 39). A part of the second silicon oxide film 62 is removed by using, for example, a wet etching method.

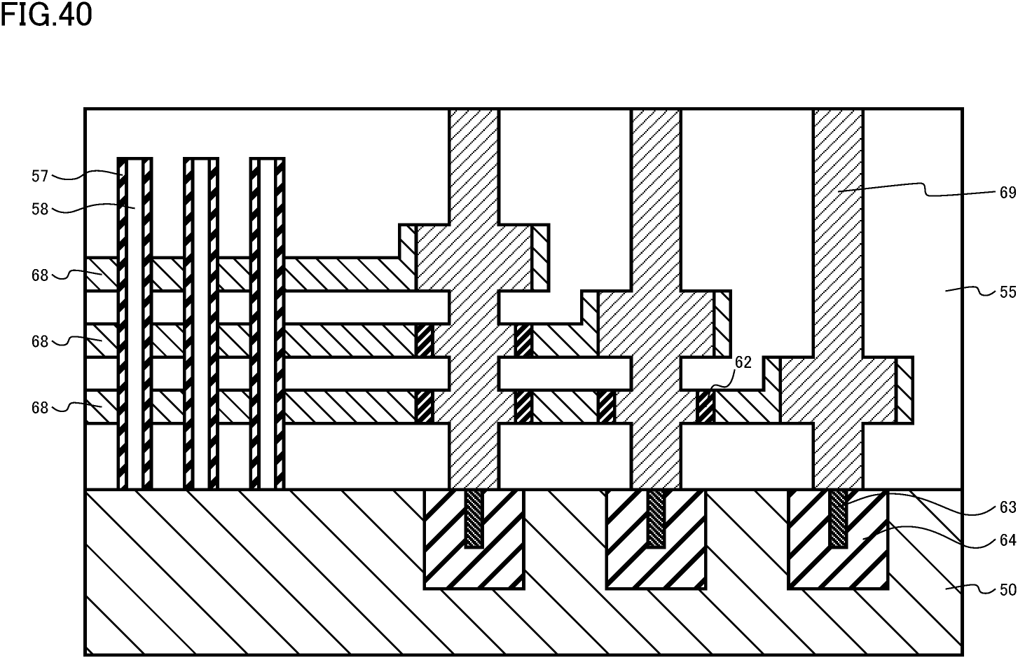

Then, the inside of the second opening 60 is buried with a second tungsten film 69 (FIG. 40). The second tungsten film 69 is formed by using, for example, a CVD method.

Then, the connection electrode 42, the wiring layer 46, and the bit line BL are formed by using a known process technique.

By the manufacturing method described above, the three-dimensional NAND flash memory according to the second embodiment shown in FIG. 17 is manufactured.

Next, the function and effect of the semiconductor memory device according to the second embodiment will be described.

In the semiconductor memory device according to the second embodiment, the third insulating layer 16 having a higher dielectric constant than the second insulating layer 14 is provided under the contact electrode CC. By providing the third insulating layer 16 having a high dielectric constant, the line of electric force between the contact electrode CC and the first semiconductor layer 11 is distributed, so that the electric field strength between the contact electrode CC and the first semiconductor layer 11 is reduced. Therefore, since the leakage current between the contact electrode CC and the first semiconductor layer 11 is suppressed, the electrical insulation between the contact electrode CC and the first semiconductor layer 11 is improved. As a result, the characteristics of the semiconductor memory device are improved.

In addition, as described above, the second insulating layer 14 is formed by radical oxidation after forming a metal oxide film, such as an aluminum oxide film, on the semiconductor layer. According to the studies by the inventors, it has been clarified that, by combining the metal oxide film and radical oxidation, the semiconductor layer can be oxidized thicker at a lower temperature than in the case of, for example, thermal oxidation.

In the semiconductor memory device according to the second embodiment including the third insulating layer 16, the second insulating layer 14 for electrically separating the contact electrode CC and the first semiconductor layer 11 from each other can be formed at a low temperature. Therefore, for example, degradation of the characteristics of the memory cell, which is formed before forming the second insulating layer 14, due to heat treatment can be suppressed.

### Modification Example

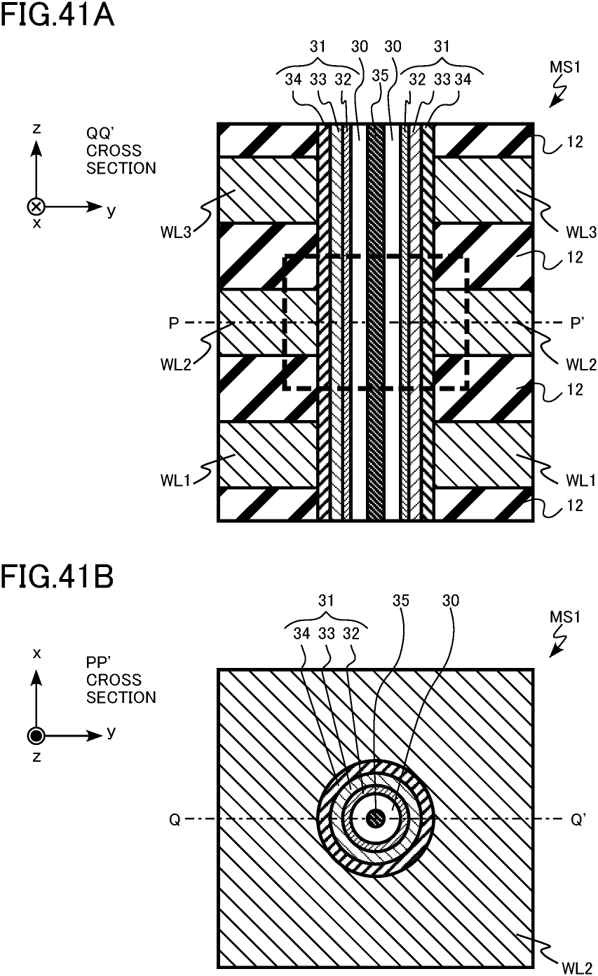

FIGS. 41A and 41B are schematic cross-sectional views of a memory cell array of a semiconductor memory device of a modification example of the second embodiment. FIG. 41A is a yz cross-sectional view of the first memory string MS1. FIG. 41A is a cross-sectional view taken along the line QQ′ of FIG. 41B. FIG. 41B is an xy cross-sectional view of the first memory string MS1. FIG. 41B is a cross-sectional view taken along the line PP′ of FIG. 41A. In FIG. 41A, the region surrounded by the dotted line is one memory cell. FIGS. 41A and 41B are diagrams corresponding to FIGS. 18A and 18B of the second embodiment.

The semiconductor memory device of the modification example of the second embodiment is different from the semiconductor memory device according to the second embodiment in that the semiconductor memory device of the modification example of the second embodiment includes a core insulating layer 35.

The core insulating layer 35 extends in the z direction. The core insulating layer 35 is surrounded by the second semiconductor layer 30. The core insulating layer 35 contains, for example, oxide. The core insulating layer 35 contains, for example, silicon oxide.

As described above, according to the second embodiment and its modification example, since the insulation between the conductive layer and the semiconductor layer is improved, it is possible to improve the characteristics of the semiconductor memory device.

Also in the semiconductor memory device according to the second embodiment, the fourth insulating layer 28 containing silicon (Si), oxygen (O), and nitrogen (N) can be formed between the second insulating layer 14 and the third insulating layer 16 as in the modification example of the first embodiment.

### Third Embodiment

A semiconductor memory device according to a third embodiment includes: a semiconductor layer extending in a first direction; a first gate electrode layer facing the semiconductor layer; a second gate electrode layer facing the semiconductor layer, and provided in the first direction of the first gate electrode layer; a charge storage layer provided between the first gate electrode layer and the semiconductor layer, and between the second gate electrode layer and the semiconductor layer; a first insulating layer provided between the first gate electrode layer and the second gate electrode layer, the first insulating layer containing silicon (Si) and oxygen (O); a second insulating layer provided between the first insulating layer and the first gate electrode layer, the second insulating layer containing silicon (Si) and oxygen (O), and density of the second insulating layer being higher than density of the first insulating layer; and a third insulating layer provided between the first insulating layer and the second gate electrode layer, the third insulating layer containing silicon (Si) and oxygen (O), and density of the third insulating layer being higher than density of the first insulating layer.

The semiconductor memory device according to the third embodiment is a three-dimensional NAND flash memory. A memory cell of the semiconductor memory device according to the third embodiment is a so-called MONOS type memory cell.

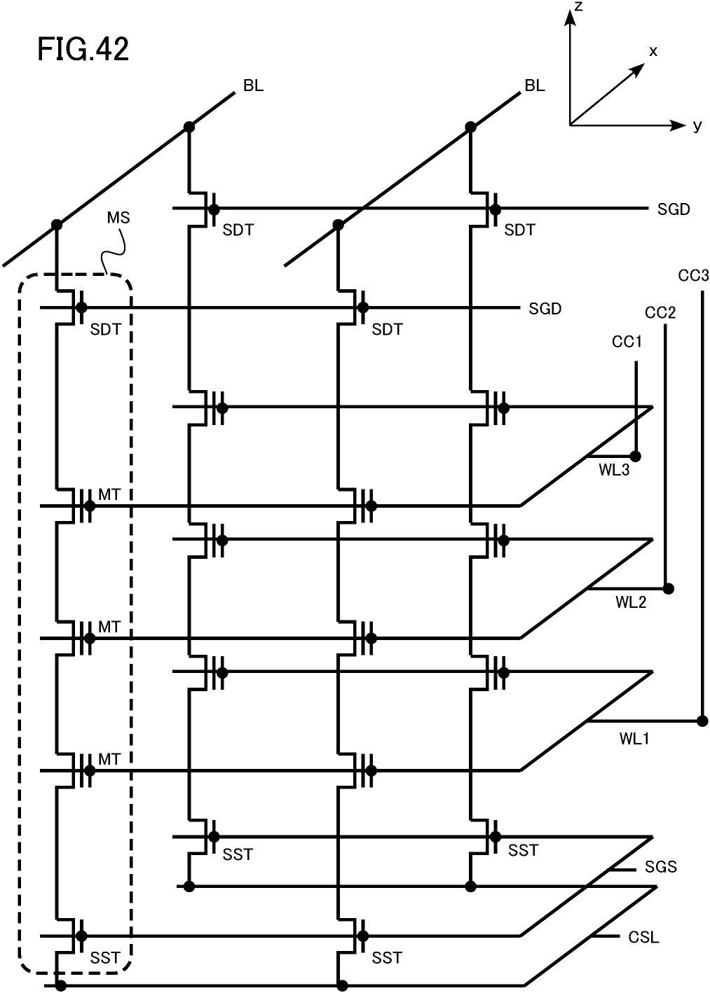

FIG. 42 is a circuit diagram of a main part of the semiconductor memory device according to the third embodiment. FIG. 42 is a circuit diagram including a memory cell array and contact electrodes of a three-dimensional NAND flash memory.

As shown in FIG. 42, the main part of the three-dimensional NAND flash memory according to the third embodiment includes a first word line WL1, a second word line WL2, a third word line WL3, a common source line CSL, a source selection gate line SGS, a plurality of drain selection gate lines SGD, a plurality of bit lines BL, a plurality of memory strings MS, a first contact electrode CC1, a second contact electrode CC2, and a third contact electrode CC3.

Hereinafter, the first word line WL1, the second word line WL2, and the third word line WL3 may be referred to as a word line WL individually or collectively. In addition, the first contact electrode CC1, the second contact electrode CC2, and the third contact electrode CC3 may be referred to as a contact electrode CC individually or collectively.

The plurality of word lines WL are arranged so as to be spaced from each other in the z direction. The plurality of word lines WL are arranged so as to be stacked in the z direction. The plurality of memory strings MS extend in the z direction. The plurality of bit lines BL extend in the x direction, for example.

Hereinafter, the x direction is defined as a third direction, the y direction is defined as a second direction, and the z direction is defined as a first direction. The x direction, the y direction, and the z direction cross each other. For example, the x direction, the y direction, and the z direction are perpendicular to each other.

As shown in FIG. 42, each memory string MS includes a source selection transistor SST, a plurality of memory cells, and a drain selection transistor SDT connected in series to each other between the common source line CSL and the bit line BL. One memory string MS can be selected by selecting one bit line BL and one drain selection gate line SGD, and one memory cell can be selected by selecting one word line WL. The word line WL is a gate electrode of a memory cell transistor MT forming the memory cell. The contact electrode CC is provided to apply a gate voltage to the word line WL.

The first word line WL1 is an example of the first gate electrode layer. The second word line WL2 is an example of the second gate electrode layer.

In addition, although FIG. 42 illustrates a case where one memory string MS includes three memory cells, the number of memory cells included in one memory string MS is not limited to three.

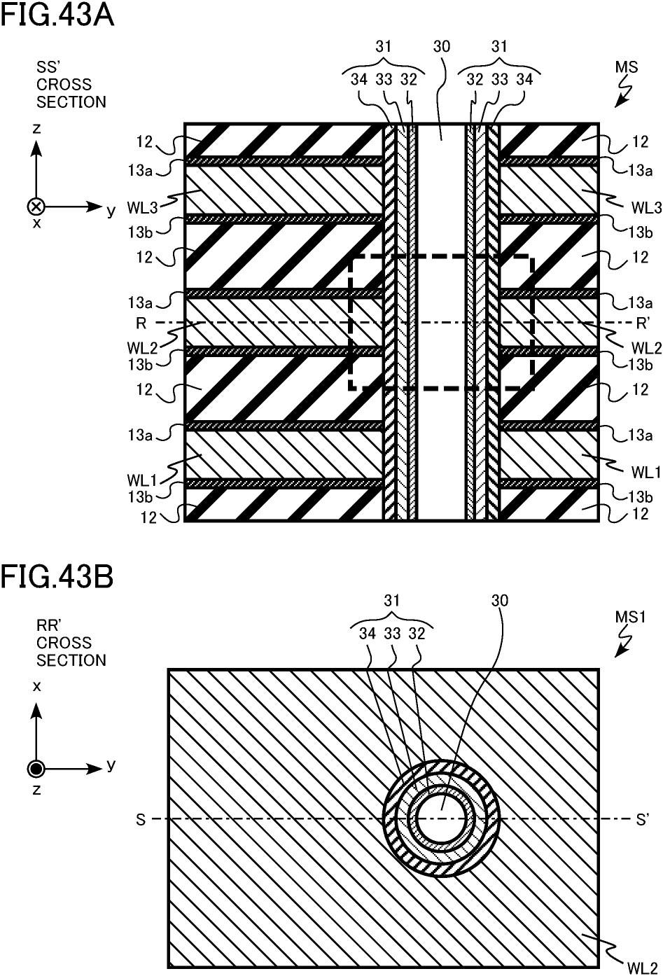

FIGS. 43A and 43B are schematic cross-sectional views of a memory cell array of the semiconductor memory device according to the third embodiment. FIGS. 43A and 43B show cross sections of a plurality of memory cells, for example, in the memory string MS surrounded by the dotted line in the memory cell array of FIG. 42.

FIG. 43A is a yz cross-sectional view of the memory string MS. FIG. 43A is a cross-sectional view taken along the line SS′ of FIG. 43B. FIG. 43B is an xy cross-sectional view of the memory string MS. FIG. 43B is a cross-sectional view taken along the line RR′ of FIG. 43A. In FIG. 43A, the region surrounded by the dotted line is one memory cell.

As shown in FIGS. 43A and 43B, the main part of the three-dimensional NAND flash memory according to the third embodiment includes a first word line WL1, a second word line WL2, a third word line WL3, a first insulating layer 12, a second insulating layer 13a, a third insulating layer 13b, a semiconductor layer 30, and a gate insulating layer 31. The gate insulating layer 31 includes a tunnel insulating layer 32, a charge storage layer 33, and a block insulating layer 34.

The semiconductor layer 30 extends in the z direction. The semiconductor layer 30 is surrounded by the word line WL. The semiconductor layer 30 has, for example, a columnar shape. The semiconductor layer 30 functions as a channel of the memory cell transistor MT.

The semiconductor layer 30 is, for example, a polycrystalline semiconductor. The semiconductor layer 30 is, for example, polycrystalline silicon.

The plurality of word lines WL face the semiconductor layer 30. The first word line WL1 faces the semiconductor layer 30. The second word line WL2 faces the semiconductor layer 30. The third word line WL3 faces the semiconductor layer 30.

The word lines WL are plate-shaped, for example. The word lines WL are made of metal, for example. The word lines WL include tungsten (W), for example. The word lines WL are made of tungsten (W), for example.

The word lines WL and the first insulating layers 12 are alternatively stacked in the first direction. The first insulating layer 12 is provided between the first word line WL1 and the second word line WL2. The first insulating layer 12 electrically separates the first word line WL1 and the second word line WL2.

The first insulating layer 12 contains silicon (Si) and oxygen (O). The first insulating layer 12 contains, for example, silicon oxide. The first insulating layer 12 is, for example, a silicon oxide.

The second insulating layer 13a is provided between the first insulating layer 12 and the word line WL. The third insulating layer 13b is provided between the first insulating layer 12 and the word line WL.

The second insulating layer 13a is provided between the first insulating layer 12 and the first word line WL1, for example. The third insulating layer 13b is provided between the first insulating layer 12 and the second word line WL2, for example.

The second insulating layer 13a and the third insulating layer 13b electrically separate the word line WL and a neighboring word line WL.

The second insulating layer 13a and the third insulating layer 13b contain silicon (Si) and oxygen (O). The second insulating layer 13a and the third insulating layer 13b contain, for example, silicon oxide. The second insulating layer 13a and the third insulating layer 13b are, for example, silicon oxide. The second insulating layer 13a and the third insulating layer 13b contain nitrogen (N), for example.

The density of the second insulating layer 13a is higher than the density of the first insulating layer 12. The density of the third insulating layer 13b is higher than the density of the first insulating layer 12. Density of insulating layers can be measured by using X-ray reflectometry (XRR).

The thickness of the first insulating layer 12 in the z direction is thicker than the thickness of the second insulating layer 13a in the z direction. The thickness of the first insulating layer 12 in the z direction is thicker than the thickness of the third insulating layer 13b in the z direction.

The thickness of the second insulating layer 13a in the z direction is equal to or larger than 1 nm and equal to or less than 5 nm, for example. The thickness of the third insulating layer 13b in the z direction is equal to or larger than 1 nm and equal to or less than 5 nm, for example.

The gate insulating layer 31 is provided between the word line WL and the semiconductor layer 30. The gate insulating layer 31 is provided between the first word line WL1 and the semiconductor layer 30. The gate insulating layer 31 is provided between the second word line WL2 and the semiconductor layer 30. The gate insulating layer 31 is provided between the third word line WL3 and the semiconductor layer 30.

The gate insulating layer 31 includes a tunnel insulating layer 32, a charge storage layer 33, and a block insulating layer 34.

The tunnel insulating layer 32 is provided between the semiconductor layer 30 and the word line WL. The tunnel insulating layer 32 has a function of allowing a charge to pass therethrough according to a voltage applied between the word line WL and the semiconductor layer 30. The tunnel insulating layer 32 contains, for example, oxide, nitride, or oxynitride. The tunnel insulating layer 32 has, for example, a stacked structure of silicon oxide and silicon nitride.

The charge storage layer 33 is provided between the tunnel insulating layer 32 and the word line WL. The charge storage layer 33 is provided between the tunnel insulating layer 32 and the block insulating layer 34.

The charge storage layer 33 has a function of trapping and storing a charge. The charge is, for example, an electron. The threshold voltage of the memory cell transistor MT changes according to the amount of charge stored in the charge storage layer 33. By using the threshold voltage change, one memory cell can store data.

The charge storage layer 33 contains, for example, nitride. The charge storage layer 33 contains, for example, silicon nitride.

The block insulating layer 34 is provided between the charge storage layer 33 and the word line WL. The block insulating layer 34 has a function of blocking the current flowing between the charge storage layer 33 and the word line WL.

The block insulating layer 34 contains, for example, oxide, acid nitride, or nitride. The block insulating layer 34 contains, for example, aluminum oxide or silicon oxide.

Next, an example of a method for manufacturing the semiconductor memory device according to the third embodiment will be described.

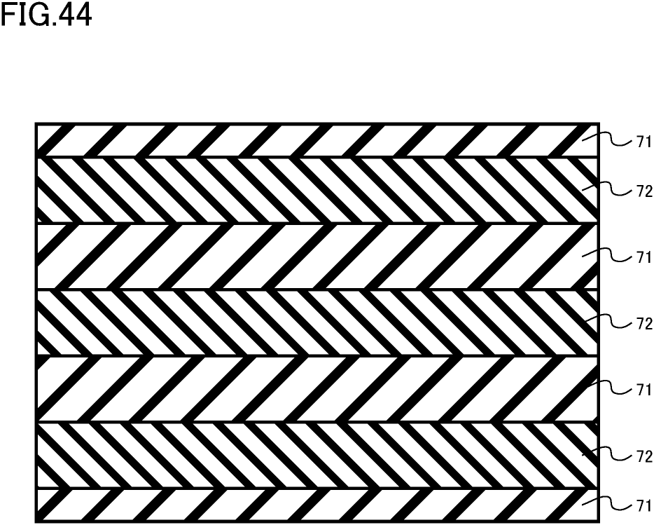

FIGS. 44 to 52 are explanatory diagrams of the method for manufacturing the semiconductor memory device according to the third embodiment. FIGS. 44 to 52 are cross-sectional views corresponding to FIG. 43A.

Hereinafter, a case where the semiconductor layer 30 is polycrystalline silicon, the first insulating layer 12 is a silicon oxide, the second insulating layer 13a is a silicon oxide, the third insulating layer 13b is a silicon oxide, and the word lines are tungsten (W) will be described as an example.

First, a first silicon oxide film 71 and a first silicon nitride film 72 are alternately formed on a substrate not shown in the drawings (FIG. 44). The first silicon oxide film 71 and the first silicon nitride film 72 are formed by using, for example, a CVD method.

A part of the first silicon oxide film 71 finally become the first insulating layer 12. A part of the first silicon nitride film 72 finally become the second insulating layer 13a and the third insulating layer 13b.

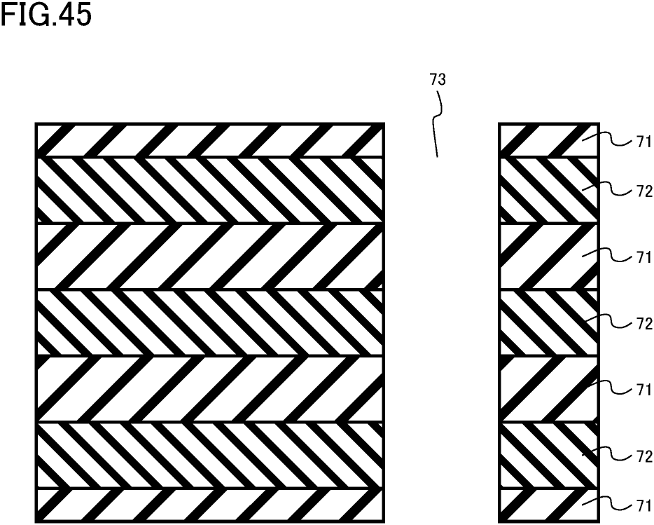

Then, a memory hole 73 penetrating through the stacked structure of the first silicon oxide films 71 and the first silicon nitride films 72 (FIG. 45). The memory hole 73 is formed by using, for example, a photolithography method and an RIE method.

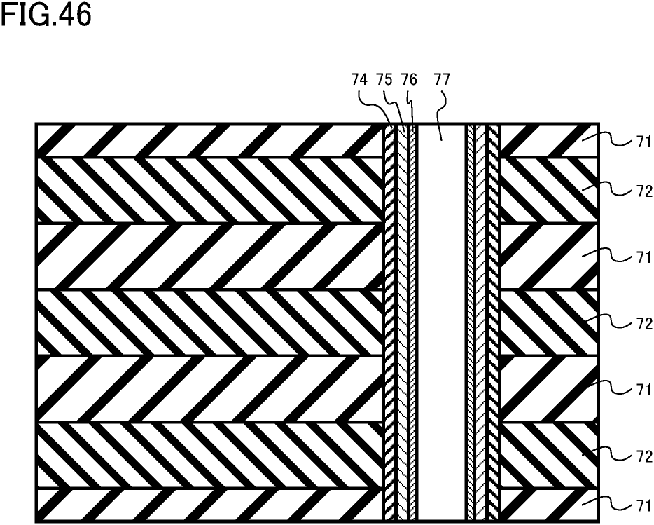

Then, a first aluminum film 74, a second silicon nitride film 75, a second silicon oxide film 76, and a polycrystalline silicon film 77 are formed in the memory hole 73 (FIG. 46). The first aluminum film 74, the second silicon nitride film 75, the second silicon oxide film 76, and the polycrystalline silicon film 77 are formed by using, for example, a CVD method.

The first aluminum film 74, the second silicon nitride film 75, the second silicon oxide film 76, and the polycrystalline silicon film 77 finally become, the block insulating layer 34, the charge storage layer 33, the tunnel insulating layer 32, and the semiconductor layer 30, respectively.

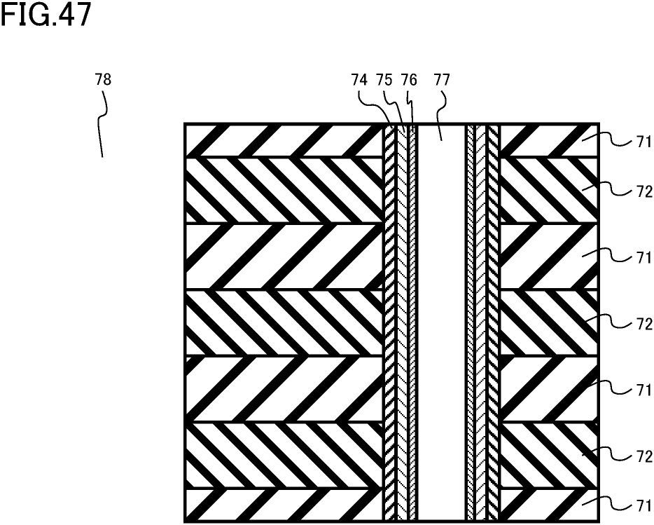

Then, a trench 78 penetrating through the stacked structure of the first silicon oxide films 71 and the first silicon nitride films 72 (FIG. 47). The trench 78 is formed by using, for example, a photolithography method and an RIE method.

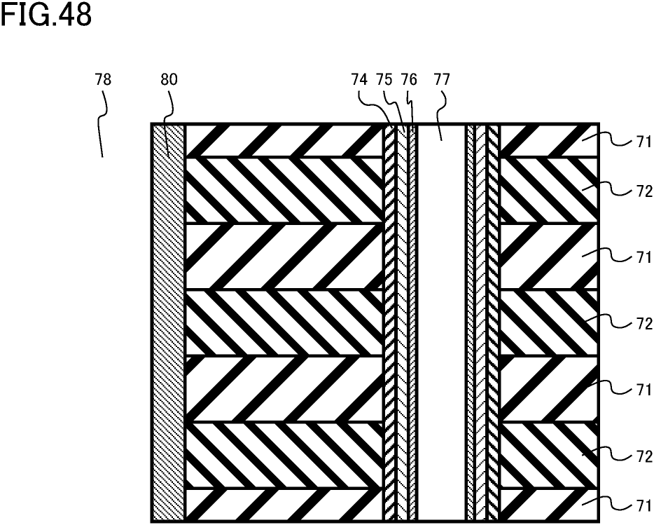

Then, a second aluminum film 80 is formed on a sidewall of trench 78 (FIG. 48). The second aluminum film 80 is formed by using, for example, a CVD method.

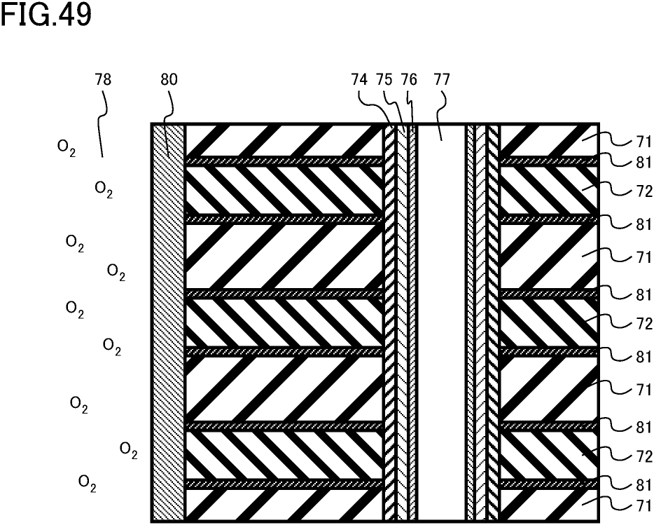

Then, a third silicon oxide film 81 is formed by oxidizing a part of the first silicon nitride film 72 by using radical oxidation (FIG. 49). The third silicon oxide film 81 is formed between the first silicon oxide film 71 and the first silicon nitride film 72. The density of the third silicon oxide film 81 is higher than the density of the first silicon oxide film 71. The third silicon oxide film 81 finally become a part of the second insulating layer 13a and a part of the third insulating layer 13b.

Oxidizing species such as oxygen radicals are diffused in the first silicon oxide film 71 after passing through the second aluminum film 80 and oxidize a part of the first silicon nitride film 72.

Radical oxidation is performed in an atmosphere containing oxygen radicals or hydroxyl radicals. For example, radical oxidation is performed in an atmosphere in which oxygen gas, hydrogen gas, and argon gas are turned into plasma. For example, radical oxidation is performed in an atmosphere in which water vapor is turned into plasma.

The method for generating oxygen radicals or hydroxyl radicals used for radical oxidation is not particularly limited. Oxygen radicals or hydroxyl radicals are generated by using, for example, an inductively coupled plasma method, a microwave plasma method, an electron cyclotron resonance method, a helicon wave method, or a thermal filament method.

The temperature of radical oxidation is, for example, equal to or more than 300° C. and equal to or less than 900° C. The pressure of radical oxidation is, for example, equal to or more than 50 Pa and equal to or less than 3000 Pa.

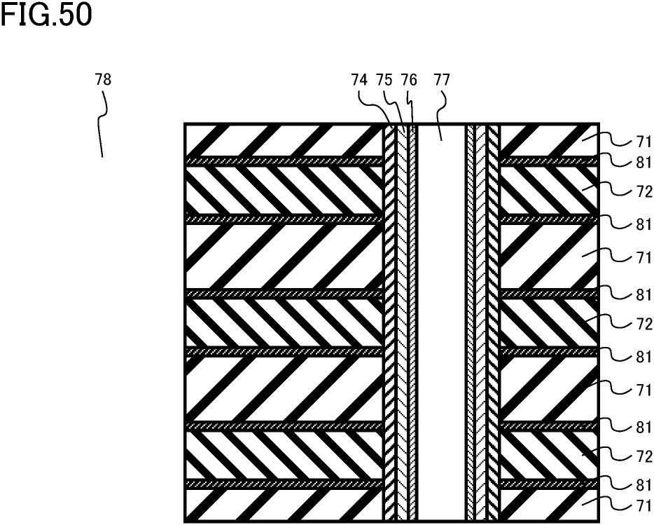

Then, the second aluminum film 80 is removed (FIG. 50). The second aluminum film 80 is removed by wet etching method, for example.

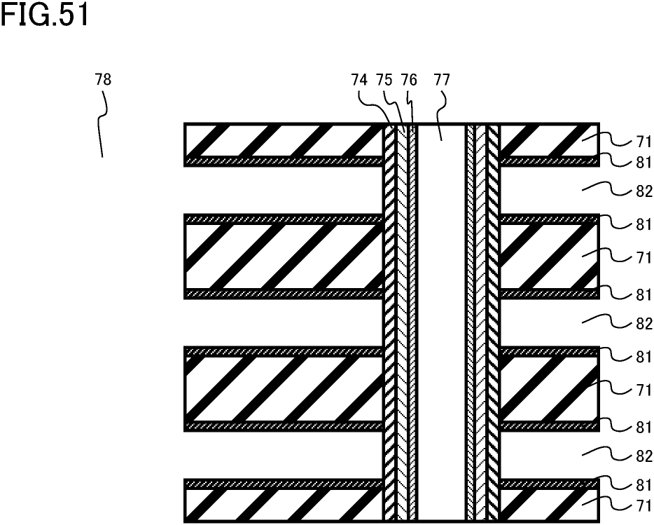

Then, the first silicon nitride film 72 is removed (FIG. 51). The first silicon nitride film 72 is selectively removed with respect to the first silicon oxide film 71 and the third silicon oxide film 81. The first silicon nitride film 72 is removed by using, for example, a wet etching method in which a wet etching solution is supplied from the trench 78 . A void 82 is formed in a portion where the first silicon nitride film 72 is removed.

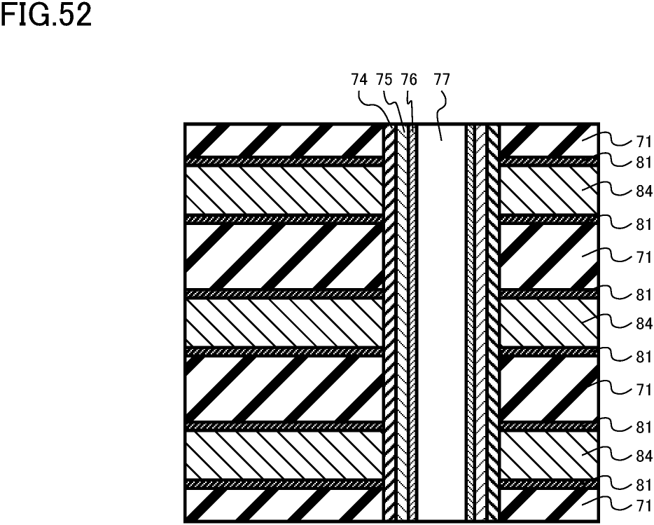

Then, a tungsten film 84 is formed in the void 82 (FIG. 52). The film 84 is formed by using a CVD method. The tungsten film 84 finally becomes the word line WL.

By the manufacturing method described above, the three-dimensional NAND flash memory according to the third embodiment shown in FIG. 43A is manufactured.

Next, the function and effect of the semiconductor memory device according to the third embodiment will be described.

In the semiconductor memory device according to the third embodiment, the second insulating layer 13a and third insulating layer 13b which have higher density than that of the first insulating layer 12 are provided between the neighboring word lines WL.

By having high density insulating layers, diffusion of tungsten in the word lines to the first insulating layer 12 is suppressed. Therefore, a breakdown voltage of insulators between the neighboring word lines WL is increased. Accordingly, the reliability of the semiconductor memory device according to the third embodiment is improved.

In addition, as described above, the second insulating layer 13a and the third insulating layer 13b are formed by oxidizing a part of the first silicon nitride film 72 with the diffusion of oxidizing species in the first silicon oxide film 71 after passing through the second aluminum film 80. According to the studies by the inventors, it has been revealed that, by making the oxidizing species pass through a metal oxide film such as aluminum oxide film before the diffusion of the oxidizing species in silicon oxide film, the diffusion of the oxidizing species is accelerated.

Therefore, for example, the lateral diffusion of the oxidizing species in the first silicon oxide film 71 of FIG. 49 is accelerated. Accordingly, the oxidation of the first silicon nitride film 72 at the interface between the first silicon oxide film 71 is accelerated.

Further, it has been revealed by the studies of the inventors, that the oxidation through a metal oxide film such as aluminum oxide film limits the oxidation amount of silicon nitride film. In other words, the oxidation of silicon nitride becomes self-limiting process with the intervention of the metal oxide film. Accordingly, it is possible to make the thickness of the third silicon oxide film 81 formed by the oxidation of the first silicon nitride film 72 limited and uniform.

While certain embodiments have been described, these embodiments have been presented by way of example only, and are not intended to limit the scope of the inventions. Indeed, the semiconductor device and the semiconductor memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor layer containing silicon (Si);
a first insulating layer provided in a first direction of the semiconductor layer;
a second insulating layer surrounded by the semiconductor layer in a first cross section perpendicular to the first direction and containing silicon (Si) and oxygen (O);
a third insulating layer surrounded by the second insulating layer in the first cross section and containing a metal element and oxygen (O);and
a conductive layer surrounded by the first insulating layer in a second cross section perpendicular to the first direction, the conductive layer provided in the first direction of the third insulating layer, and the conductive layer spaced from the semiconductor layer.

2. The semiconductor device according to claim 1,
wherein the conductive layer is in contact with the third insulating layer.

3. The semiconductor device according to claim 1,
wherein the first insulating layer is in contact with the semiconductor layer.

4. The semiconductor device according to claim 1,
wherein the third insulating layer is spaced from the semiconductor layer.

5. The semiconductor device according to claim 1,
wherein a dielectric constant of the third insulating layer is higher than a dielectric constant of the second insulating layer.

6. The semiconductor device according to claim 1,
wherein the conductive layer is in contact with the second insulating layer.

7. The semiconductor device according to claim 1,
wherein the metal element is at least one metal element selected from a group consisting of aluminum (Al), hafnium (Hf), zirconium (Zr), lanthanum (La), yttrium (Y), titanium (Ti), nickel (Ni), zinc (Zn), indium (In), tin (Sn), gallium (Ga), and tungsten (W).

8. The semiconductor device according to claim 1, further comprising:
a fourth insulating layer provided between the second insulating layer and the third insulating layer and containing silicon (Si), oxygen (O), and nitrogen (N).

9. A semiconductor memory device, comprising:
a first semiconductor layer containing silicon (Si);
a first insulating layer provided in a first direction of the first semiconductor layer;
a second insulating layer surrounded by the first semiconductor layer in a first cross section perpendicular to the first direction and containing silicon (Si) and oxygen (O);
a third insulating layer surrounded by the second insulating layer in the first cross section and containing a metal element and oxygen (O);
a conductive layer extending in the first direction, the conductive layer surrounded by the first insulating layer in a second cross section perpendicular to the first direction, the conductive layer provided in the first direction of the third insulating layer, and the conductive layer spaced from the first semiconductor layer;
a first gate electrode layer provided in the first direction of the first semiconductor layer and electrically connected to the conductive layer;
a second semiconductor layer extending in the first direction; and
a charge storage layer provided between the first gate electrode layer and the second semiconductor layer.

10. The semiconductor memory device according to claim 9,
wherein the conductive layer is in contact with the first gate electrode layer.

11. The semiconductor memory device according to claim 9, further comprising:
a second gate electrode layer provided in the first direction of the first semiconductor layer, the second gate electrode provided in the first direction of the first gate electrode layer, and the second gate electrode electrically separated from the conductive layer,
wherein the charge storage layer is provided between the second gate electrode layer and the second semiconductor layer.

12. The semiconductor memory device according to claim 11,
wherein the conductive layer is spaced from the second gate electrode layer.

13. The semiconductor memory device according to claim 11,
wherein the conductive layer is surrounded by the first gate electrode layer in a third cross section perpendicular to the first direction, and the conductive layer is surrounded by the second gate electrode layer in a fourth cross section perpendicular to the first direction.

14. The semiconductor memory device according to claim 9,
wherein the conductive layer is in contact with the third insulating layer.

15. The semiconductor memory device according to claim 9,
wherein the first insulating layer is in contact with the first semiconductor layer.

16. The semiconductor memory device according to claim 9,
wherein the third insulating layer is spaced from the first semiconductor layer.

17. The semiconductor memory device according to claim 9,
wherein a dielectric constant of the third insulating layer is higher than a dielectric constant of the second insulating layer.

18. The semiconductor memory device according to claim 9,
wherein the conductive layer is in contact with the second insulating layer.

19. The semiconductor memory device according to claim 9, further comprising:
a fourth insulating layer provided between the second insulating layer and the third insulating layer and containing silicon (Si), oxygen (O), and nitrogen (N).

20. The semiconductor memory device according to claim 9,
wherein the metal element is at least one metal element selected from a group consisting of aluminum (Al), hafnium (Hf), zirconium (Zr), lanthanum (La), yttrium (Y), titanium (Ti), nickel (Ni), zinc (Zn), indium (In), tin (Sn), gallium (Ga), and tungsten (W).

21. A semiconductor memory device, comprising:
a semiconductor layer extending in a first direction;
a first gate electrode layer facing the semiconductor layer;
a second gate electrode layer facing the semiconductor layer, and provided in the first direction of the first gate electrode layer;
a charge storage layer provided between the first gate electrode layer and the semiconductor layer, and between the second gate electrode layer and the semiconductor layer;
a first insulating layer provided between the first gate electrode layer and the second gate electrode layer, the first insulating layer containing silicon (Si) and oxygen (O);
a second insulating layer provided between the first insulating layer and the first gate electrode layer, the second insulating layer containing silicon (Si) and oxygen (O), and density of the second insulating layer being higher than density of the first insulating layer; and
a third insulating layer provided between the first insulating layer and the second gate electrode layer, the third insulating layer containing silicon (Si) and oxygen (O), and density of the third insulating layer being higher than the density of the first insulating layer.

22. The semiconductor memory device according to claim 21,
wherein a thickness of the first insulating layer in the first direction is thicker than a thickness of the second insulating layer in the first direction, and
the thickness of the first insulating layer in the first direction is thicker than a thickness of the third insulating layer in the first direction.

23. The semiconductor memory device according to claim 21,
wherein a thickness of the second insulating layer in the first direction is equal to or less than 5 nm, and
a thickness of the third insulating layer in the first direction is equal to or less than 5 nm.
